(19) United States
(12) Patent Application Publication
(10) Pub. No.: US 2026/0282776 A1
(43) Pub. Date: Sep. 17, 2026

(54) SELECTIVELY DEPOSITING SILICON OXIDE ON A DIELECTRIC SURFACE OF A SUBSTRATE

(71) Applicant: Lam Research Corporation, Fremont, CA (US)

(72) Inventors: Nupur BIHARI, Tualatin, OR (US); Joel David SMITH, Tualatin, OR (US); Dennis HAUSMANN, Lake Oswego, OR (US); Kevin MCLAUGHLIN, Sherwood, OR (US); Kapu Sirish REDDY, Portland, OR (US); Bart J. VAN SCHRAVENDIJK, Palo Alto, CA (US); Jason Nathaniel BELLING, Tualatin, OR (US)

(21) Appl. No.: 19/473,085

(22) PCT Filed: Apr. 8, 2024
(86) PCT No.: PCT/US2024/023611

§ 371 Date: Oct. 6, 2025

Related U.S. Application Data
(60) Provisional application No. 63/495,278, filed on Apr. 10, 2023.
(60) Provisional application No. 63/496,912, filed on Apr. 18, 2023.

(51) Int. Cl. H10P 14/60; H01J 37/32; H10P 14/692

(52) U.S. Cl. CPC H10P 14/6514; H01J 37/32449; H10P 14/6336; H10P 14/6506; H10P 14/6684; H10P 14/69215; H10P 14/69391; H01J 2237/3321

(57) ABSTRACT

A method for selectively depositing silicon oxide on a substrate comprises exposing the substrate to a silicon-containing inhibitor to selectively adsorb the silicon-containing inhibitor to a metal surface of the substrate. The silicon-containing inhibitor comprises one or more organic ligands. The method further comprises forming a catalytic layer on a dielectric surface of the substrate by exposing the substrate to a metal-containing precursor to adsorb the metal-containing precursor to the dielectric surface. The silicon-containing inhibitor inhibits adsorption of the metal-containing precursor to the metal surface. The method further comprises exposing the substrate to a silanol-based silicon oxide precursor, wherein the catalytic layer catalyzes a conversion of the silanol-based silicon oxide precursor to silicon oxide.

### BACKGROUND

In integrated circuit fabrication, metal lines can be embedded in dielectric material. Formation of such embedded metal lines requires patterning and etching of the dielectric material to form vias and trenches, followed by filling of these vias and trenches with a metal. In some fabrication processes, a second layer of the dielectric material is deposited and is again patterned to form vias and trenches. These vias and trenches are again filled with the metal. This forms a stack of dielectric layers having embedded metal lines. The metal lines form conductive paths of an integrated circuit. However, as integrated circuit fabrication moves towards smaller technology nodes, it becomes technologically challenging to selectively deposit the dielectric layers in accurate locations.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to selectively depositing silicon oxide on a substrate, the substrate comprising a metal surface and a dielectric surface. One example provides a method for selectively depositing silicon oxide on a substrate. The substrate comprises a metal surface and a dielectric surface. The method comprises exposing the substrate to a silicon-containing inhibitor to selectively adsorb the silicon-containing inhibitor to the metal surface of the substrate. The silicon-containing inhibitor comprises one or more organic ligands. The method further comprises forming a catalytic layer on the dielectric surface of the substrate by exposing the substrate to a metal-containing precursor to adsorb the metal-containing precursor to the dielectric surface. The silicon-containing inhibitor inhibits adsorption of the metal-containing precursor to the metal surface. The method further comprises exposing the substrate to a silanol-based silicon oxide precursor, wherein the catalytic layer catalyzes a conversion of the silanol-based silicon oxide precursor to silicon oxide.

In some such examples, the method comprises pre-treating the substrate with a plasma comprising oxygen and hydrogen before exposing the substrate to the silicon-containing inhibitor.

Additionally or alternatively, in some such examples, the silicon-containing inhibitor comprises a head group comprising at least one Si—H group and a tail group comprising an organic moiety.

Additionally or alternatively, in some such examples, the silicon-containing inhibitor comprises one or more of n-octadecylsilane, tridecylsilane, dodecylsilane, undecylsilane, decylsilane, decan-4-ylsilane, nonylsilane, nonan-4-ylsilane, octan-2-ylsilane, octylsilane, heptylsilane, heptan-4-ylsilane, (tridecafluoro-1,1,2,2-tetra-hydrooctyl) silane, or 10-undecenylsilane.

Additionally or alternatively, in some such examples, the metal-containing precursor comprises one or more of methyl aluminum propoxide, methyl aluminum isopropoxide, methyl aluminum butoxide, methyl aluminum t-butoxide, methyl aluminum ethoxide, dimethyl aluminum propoxide, dimethyl aluminum isopropoxide, dimethyl aluminum butoxide, dimethyl aluminum t-butoxide, dimethyl aluminum ethoxide, ethyl aluminum propoxide, ethyl aluminum isopropoxide, ethyl aluminum butoxide, ethyl aluminum t-butoxide, ethyl aluminum ethoxide, diethyl aluminum propoxide, diethyl aluminum isopropoxide, diethyl aluminum butoxide, diethyl aluminum t-butoxide, diethyl aluminum ethoxide, propyl aluminum propoxide, propyl aluminum isopropoxide, propyl aluminum butoxide, propyl aluminum t-butoxide, propyl aluminum ethoxide, dipropyl aluminum propoxide, dipropyl aluminum isopropoxide, dipropyl aluminum butoxide, dipropyl aluminum t-butoxide, or dipropyl aluminum ethoxide.

Additionally or alternatively, in some such examples, forming the catalytic layer further comprises introducing an oxidizing agent into a processing chamber in which the substrate is located to thereby oxidize the aluminum-containing precursor and form an aluminum oxide layer on the dielectric surface.

Additionally or alternatively, in some such examples, the silanol-based silicon oxide precursor comprises a silanol with one or more alkoxy groups, each alkoxy group comprising one to seven carbon atoms.

Additionally or alternatively, in some such examples, the metal surface of the substrate comprises one or more of copper, cobalt, tungsten, ruthenium, rhodium, iridium, tantalum, titanium, hafnium, zirconium, or molybdenum.

Additionally or alternatively, in some such examples, the dielectric surface of the substrate comprises one or more of silicon dioxide, doped silicon dioxide, silicon nitride, silicon carbide, silicon oxycarbide, silicon oxynitride, or silicon carbon nitride.

Additionally or alternatively, in some such examples, exposing the substrate to the silanol-based silicon oxide precursor comprises using flow-over-vapor to introduce the silanol-based silicon oxide precursor into a processing chamber in which the substrate is located.

Additionally or alternatively, in some such examples, the method further comprises reapplying the catalytic layer at an intermediate time after the substrate is exposed to the silanol-based silicon oxide precursor.

Additionally or alternatively, in some such examples, exposing the substrate to the silanol-based silicon oxide precursor comprises introducing the silanol-based silicon oxide precursor in a plurality of pulses.

Another example provides a processing tool. The processing tool comprises a processing chamber. The processing tool further comprises a substrate holder positioned within the processing chamber. The processing tool further comprises flow control hardware configured to control a flow of each of one or more processing chemicals into the processing chamber. The processing tool further comprises a controller configured to control the flow control hardware to expose a substrate on the substrate holder to a silicon-containing inhibitor to selectively adsorb the silicon-containing inhibitor to a metal surface of the substrate. The controller is further configured to control the flow control hardware to form a catalytic layer on a dielectric surface of the substrate by exposing the substrate to an aluminum-containing precursor to adsorb the aluminum-containing precursor to the dielectric surface. The controller is further configured to control the flow control hardware to expose the substrate to a silanol-based silicon oxide precursor.

Additionally or alternatively, in some such examples, the processing tool further comprises a silicon-containing inhibitor source holding the silicon-containing inhibitor, wherein the silicon-containing inhibitor comprises a head group comprising at least one Si—H group and a tail group comprising an organic moiety.

Additionally or alternatively, in some such examples, the processing tool further comprises an aluminum-containing precursor source holding the aluminum-containing precursor, wherein the aluminum-containing precursor comprises one or more of methyl aluminum propoxide, methyl aluminum isopropoxide, methyl aluminum butoxide, methyl aluminum t-butoxide, methyl aluminum ethoxide, dimethyl aluminum propoxide, dimethyl aluminum isopropoxide, dimethyl aluminum butoxide, dimethyl aluminum t-butoxide, dimethyl aluminum ethoxide, ethyl aluminum propoxide, ethyl aluminum isopropoxide, ethyl aluminum butoxide, ethyl aluminum t-butoxide, ethyl aluminum ethoxide, diethyl aluminum propoxide, diethyl aluminum isopropoxide, diethyl aluminum butoxide, diethyl aluminum t-butoxide, diethyl aluminum ethoxide, propyl aluminum propoxide, propyl aluminum isopropoxide, propyl aluminum butoxide, propyl aluminum t-butoxide, propyl aluminum ethoxide, dipropyl aluminum propoxide, dipropyl aluminum isopropoxide, dipropyl aluminum butoxide, dipropyl aluminum t-butoxide, or dipropyl aluminum ethoxide.

Additionally or alternatively, in some such examples, the processing tool further comprises an oxidizing agent source, and wherein the controller is further configured to control the flow control hardware to introduce an oxidizing agent from the oxidizing-agent source into the processing chamber to thereby oxidize the aluminum-containing precursor and form an aluminum oxide layer on the dielectric surface.

Additionally or alternatively, in some such examples, the controller is further configured to control the flow control hardware to introduce the silanol-based silicon oxide precursor into the processing chamber in a plurality of pulses.

Another example provides a method for selectively depositing silicon oxide on a substrate, the substrate comprising a metal surface and a dielectric surface. The method comprises exposing the substrate to a plasma comprising oxygen and hydrogen to pre-treat the substrate. The method further comprises, after pre-treating the substrate, exposing the substrate to a silicon-containing inhibitor to selectively adsorb the silicon-containing inhibitor to the metal surface of the substrate, the silicon-containing inhibitor comprising one or more organic ligands. The method further comprises forming a catalytic layer on the dielectric surface of the substrate by exposing the substrate to an aluminum-containing precursor to adsorb the aluminum-containing precursor to the dielectric surface, wherein the silicon-containing inhibitor inhibits adsorption of the aluminum-containing precursor to the metal surface. The method further comprises exposing the substrate to a silanol-based silicon oxide precursor, wherein the catalytic layer catalyzes a conversion of the silanol-based silicon oxide precursor to silicon oxide.

Additionally or alternatively, in some such examples, forming the catalytic layer further comprises introducing an oxidizing agent into a processing chamber in which the substrate is located to thereby oxidize the aluminum-containing precursor and form an aluminum oxide layer on the dielectric surface.

Additionally or alternatively, in some such examples, exposing the substrate to the silanol-based silicon oxide precursor comprises introducing the silanol-based silicon oxide precursor in a plurality of pulses.

Another example provides a method for processing a substrate. The method comprises exposing the substrate to a plasma comprising an inert gas to pre-treat the substrate. The method further comprises exposing the substrate to a silicon-containing inhibitor to selectively adsorb the silicon-containing inhibitor to a metal surface and a barrier layer surface of the substrate. The silicon-containing inhibitor comprises one or more organic moieties. The method further comprises exposing the substrate to a metal-containing precursor to adsorb the metal-containing precursor to a dielectric surface of the substrate. The silicon-containing inhibitor inhibits adsorption of the metal-containing precursor to the metal surface and the barrier layer surface.

In some such examples, the inert gas comprises helium.

Additionally or alternatively, in some such examples, the plasma further comprises one or more of hydrogen or ammonia.

Additionally or alternatively, in some such examples, the silicon-containing inhibitor comprises one or more of n-octadecylsilane, tridecylsilane, dodecylsilane, undecylsilane, decylsilane, decan-4-ylsilane, nonylsilane, nonan-4-ylsilane, octan-2-ylsilane, octylsilane, heptylsilane, heptan-4-ylsilane, (tridecafluoro-1,1,2,2-tetra-hydrooctyl) silane, or 10-undecenylsilane.

Additionally or alternatively, in some such examples, the metal-containing precursor comprises an aluminum-containing precursor.

Additionally or alternatively, in some such examples, the barrier layer comprises one or more of tantalum, tantalum nitride, rhodium, or iridium.

Additionally or alternatively, in some such examples, the plasma comprises a capacitively coupled plasma.

Additionally or alternatively, in some such examples, the plasma comprises a power within a range of 50 to 600 W (watts).

Additionally or alternatively, in some such examples, the plasma comprises an inductively coupled plasma.

Additionally or alternatively, in some such examples, the plasma comprises a power within a range of 2000-6000 W.

Additionally or alternatively, in some such examples, the dielectric surface of the substrate comprises one or more of silicon dioxide, doped silicon dioxide, silicon nitride, silicon carbide, silicon oxycarbide, silicon oxynitride, or silicon carbon nitride.

Another example provides a processing tool. The processing tool comprises a processing chamber. The processing tool further comprises a substrate holder positioned within the processing chamber. The processing tool further comprises a plasma generator. The processing tool further comprises flow control hardware configured to control a flow of each of one or more processing chemicals into the processing chamber. The processing tool further comprises a controller configured to control the flow control hardware and the plasma generator to expose a substrate on the substrate holder to a plasma comprising an inert gas. The controller is further configured to control the flow control hardware to introduce expose the substrate on the substrate holder to a silicon-containing inhibitor to selectively adsorb the silicon-containing inhibitor to a metal surface and a barrier layer surface of the substrate. The controller is further configured to control the flow control hardware to expose the substrate to a metal-containing precursor to adsorb the metal-containing precursor to the dielectric surface.

In some such examples, the processing tool further comprises a silicon-containing inhibitor source holding the silicon-containing inhibitor, wherein the silicon-containing inhibitor comprises a head group comprising at least one Si—H group and a tail group comprising an organic moiety.

Additionally or alternatively, in some such examples, the processing tool further comprises a metal-containing precursor source, wherein the metal-containing precursor source comprises an aluminum-containing precursor.

Additionally or alternatively, in some such examples, the processing tool further comprises an inert gas source, wherein the inert gas source comprises helium.

Additionally or alternatively, in some such examples, the plasma generator comprises a capacitively-coupled plasma generator, and the instructions are executable to control the plasma generator to form the plasma with a power within a range of 50 to 600 W (watts).

Another example provides a method for selectively depositing silicon oxide on a substrate, the substrate comprising a metal surface and a dielectric surface. The method comprises exposing the substrate to a plasma comprising helium to pre-treat the substrate. The method further comprises exposing the substrate to a silicon-containing inhibitor to selectively adsorb the silicon-containing inhibitor to a metal surface and a barrier layer surface of the substrate, the silicon-containing inhibitor comprising one or more organic moieties. The method further comprises exposing the substrate to a metal-containing precursor to adsorb the metal-containing precursor to a dielectric surface of the substrate. The silicon-containing inhibitor inhibits adsorption of the metal-containing precursor to the metal surface and the barrier layer surface.

Additionally or alternatively, in some such examples, the barrier layer surface comprises one or more of tantalum, rhodium, or iridium.

Additionally or alternatively, in some such examples, the plasma omits hydrogen-containing species.

Additionally or alternatively, in some such examples, the plasma is a capacitively coupled plasma comprising a power within a range of 50-600 W (watts).

### BRIEF DESCRIPTION OF THE DRAWINGS

FIGS. 1A-1F schematically show a cross-sectional view of a substrate at various stages in an example silicon oxide deposition process.

FIG. 2 shows an example timing diagram that can be used to expose a substrate to a silanol-based silicon oxide precursor in an example silicon oxide deposition process.

FIG. 3 shows a schematic illustration of an example film stack that can be fabricated using the silicon oxide deposition process illustrated in FIGS. 1A-1F.

FIG. 4 shows an example of a processing tool that can be used to deposit silicon oxide on the substrate of FIG. 1.

FIG. 5 is a block diagram of an example processing system that can be used to deposit silicon oxide on the substrate of FIG. 1.

FIGS. 6A-6B show a flow diagram of an example method for selectively depositing silicon oxide on a substrate comprising a metal surface and a dielectric surface.

FIGS. 7A-7F schematically show a cross-sectional view of a substrate at various stages in another example silicon oxide deposition process utilizing a plasma pre-treatment with an inert gas.

FIG. 8 shows an example timing diagram that can be used to expose a substrate to a silanol-based silicon oxide precursor in an example silicon oxide deposition process.

FIG. 9 shows a schematic illustration of an example film stack that can be fabricated using the silicon oxide deposition process illustrated in FIGS. 7A-7F.

FIG. 10 shows an example of a processing tool that can be used to perform a plasma pretreatment on a substrate, selectively adsorb a silicon-containing inhibitor to the substrate, and/or deposit a dielectric film on the substrate according to the process illustrated in FIGS. 7A-7F.

FIGS. 11A-11B show a flow diagram illustrating an example method for processing a substrate.

FIG. 12 shows a schematic diagram of an example computing system.

### DETAILED DESCRIPTION

The term “alcohol” generally represents hydrocarbon compounds comprising general formula R—OH, where R is an aryl or aliphatic group. Alcohols can have more than one OH group (polyols), such as diols, which have two OH functional groups. Example alcohols comprise methanol, ethanol, t-butyl alcohol, n-butyl alcohol, 2-butyl alcohol, and propanol.

The term “aliphatic” generally represents a non-aromatic hydrocarbon group. Example aliphatic groups can comprise one carbon atom to 50 carbon atoms (C1-50). Example aliphatic functional groups include alkyl, alkenyl, and alkynyl, including cyclic versions thereof. The term “aliphatic” also includes straight- and branched-chain arrangements thereof, and stereo and position isomers thereof. The term “aliphatic” also includes partially or fully substituted variants thereof.

The term “alkenyl” generally represents an unsaturated monovalent hydrocarbon group with at least one carbon-carbon double bond. Example alkenyls include functional groups having at least two carbon atom to 50 carbon atoms (C2-50). An alkene or alkenyl group can be branched, straight-chain, cyclic (e.g., cycloalkenyl), and can be cis or trans (e.g., E or Z). An example alkenyl includes an optionally substituted C2-24 alkyl group having one or more double bonds. The alkenyl group can be monovalent or multivalent (e.g., bivalent) by removing one or more hydrogens to form appropriate attachment to the parent molecular group or appropriate attachments between the parent molecular group and another substitution. The alkenyl group can also be substituted or unsubstituted. For example, the alkenyl group can be substituted with one or more substitution groups, as described herein for alkyl.

The term “alkenylene” generally represents a multivalent (e.g., bivalent) form of an alkenyl group, as described herein. The alkenylene group can be substituted or unsubstituted. For example, the alkenylene group can be substituted with one or more substitution groups, as described herein for alkyl.

The term “alkoxide” generally represents a ligand comprising an oxygen bound to a hydrocarbon moiety. The hydrocarbon moiety can be unsubstituted, partially substituted, or fully substituted. Example hydrocarbon moieties include alkyl, alkenyl, and alkynyl moiety, including linear, branched, and cyclic variants thereof.

The term “silanol-based silicon oxide precursor” generally represents a compound including a silicon atom bound to one or more alkoxy groups and at least one hydroxyl group. The term “alkoxy group” generally represents an alkyl group that is bonded to oxygen.

The term “alkyl” generally represents a saturated monovalent hydrocarbon group. Example alkyl groups include functional groups having at least one carbon atom to 50 carbon atoms (C1-50), wherein the saturated monovalent hydrocarbon can be derived from removing one hydrogen atom from one carbon atom of a parent alkane compound. An alkyl group can be branched, straight-chain, or cyclic. An example alkyl includes a branched or unbranched saturated hydrocarbon group of 1 to 24 carbon atoms. More specific alkyls include methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. An alkyl group can also be substituted or unsubstituted. An alkyl group can be monovalent or multivalent (e.g., bivalent) by removing one or more hydrogens to form appropriate attachment to the parent molecular group or appropriate attachment between the parent molecular group and another substitution. For example, an alkyl group can be substituted with one, two, three or, in the case of alkyl groups of two carbons or more, four substituents. Example substituents include (1) C1-6 alkoxy (e.g., —O—R, in which R is C1-6 alkyl); (2) C1-6 alkylsulfinyl (e.g., —S(O)—R, in which R is C1-6 alkyl); (3) C1-6 alkylsulfonyl (e.g., —SO₂—R, in which R is C1-6 alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as described herein, or any combination thereof, or R¹ and R², taken together with the nitrogen atom to which each are attached, form a heterocyclyl group, as described herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C3-8 cycloalkyl; (12) halo; (13) heterocyclyl (e.g., as described herein, such as a 5-, 6- or 7-membered ring containing one, two, three, or four non-carbon heteroatoms); (14) heterocyclyloxy (e.g., —O—R, in which R is heterocyclyl, as described herein); (15) heterocyclyloyl (e.g., —C(O)—R, in which R is heterocyclyl, as described herein); (16) hydroxyl (e.g., —OH); (17) N-protected amino; (18) nitro (e.g., —NO₂); (19) oxo (e.g., ═O); (20) C1-6 thioalkoxy (e.g., —S—R, in which R is alkyl); (21) thiol (e.g., —SH); (22) —CO₂R¹, where R¹ comprises (a) hydrogen, (b) C1-6 alkyl, (c) C4-18 aryl, or (d) C1-6 alkyl-C4-18 aryl (e.g., -L-R, in which L is C1-6 alkyl and R is C4-18 aryl); (23) —C(O)NR¹R², where each of R¹ and R² independently comprises (a) hydrogen, (b) C1-6 alkyl, (c) C4-18 aryl, or (d) C1-6 alkyl-C4-18 aryl (e.g., -L-R, in which L is C₁₋₆ alkyl and R is C4-18 aryl); (24) —SO₂R¹, where R¹ comprises (a) C1-6 alkyl, (b) C4-18 aryl, or (c) C1-6 alkyl-C4-18 aryl (e.g., -L-R, in which L is C1-6 alkyl and R is C4-18 aryl); (25) —SO₂NR¹R², where each of R¹ and R² independently comprises (a) hydrogen, (b) C1-6 alkyl, (c) C4-18 aryl, or (d) C1-6 alkyl-C4-18 aryl (e.g., -L-R, in which L is C₁₋₆ alkyl and R is C4-18 aryl); (26) —SiR³R²R³, where each of R¹ and R² and R³ independently comprises (a) hydrogen, (b) halo, such as F, Cl, Br, or I, (c) C1-6 alkyl, (d) C2-6 alkenyl, (e) C2-6 alkynyl, or (f) C1-6 alkoxy (e.g., —OR, in which R is C1-6 alkyl); or (27) —NR¹R², where each of R¹ and R² independently comprises (a) hydrogen, (b) an N-protecting group, (c) C1-6 alkyl, (d) C2-6 alkenyl, (e) C2-6 alkynyl, (f) C4-18 aryl, (g) C1-6 alkyl-C4-18 aryl (e.g., -L-R, in which L is C1-6 alkyl and R is C4-18 aryl), (h) C3-8 cycloalkyl, or (i) C1-6 alkyl-C3-8 cycloalkyl (e.g., -L-R, in which L is C1-6 alkyl and R is C3-8 cycloalkyl), wherein in one example no two groups are bound to the nitrogen atom through a carbonyl group or a sulfonyl group. The alkyl group can be a primary, secondary, or tertiary alkyl group substituted with one or more substituents (e.g., one or more halo or alkoxy). In some examples, an unsubstituted alkyl group comprises a C1-3, C1-6, C1-12, C1-16, C1-18, C1-20, or C1-24 alkyl group.

The term “alkylene” generally represents a multivalent (e.g., bivalent) form of an alkyl group, as described herein. Example alkylene groups include methylene, ethylene, propylene, butylene, etc. In some example, the alkylene group comprises a C2-24 alkylene group. The alkylene group can be branched or unbranched. The alkylene group can also be substituted or unsubstituted. For example, the alkylene group can be substituted with one or more substitution groups, as described herein for alkyl.

The term “alkyleneoxy” generally represents an alkylene group, as described herein, attached to a parent molecular group through an oxygen atom.

The term “alkynyl” generally represents an unsaturated monovalent hydrocarbon having at least one carbon-carbon triple bond. Example alkynyls include groups with two carbon atoms to fifty carbon atoms (C2-50), wherein the unsaturated monovalent hydrocarbon can be derived from removing one hydrogen atom from one carbon atom of a parent alkyne. An alkynyl group can be branched, straight-chain, or cyclic (e.g., cycloalkynyl). An example alkynyl includes an optionally substituted C2-24 alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

The term “alkynylene” generally represents a multivalent (e.g., bivalent) form of an alkynyl group, as described herein. The alkynylene group can be substituted or unsubstituted. For example, the alkynylene group can be substituted with one or more substitution groups, as described herein for alkyl.

The term “aluminum-containing precursor” generally represents compound that includes one or more aluminum atoms for forming an aluminum-containing thin film. An aluminum-containing precursor can be used to form aluminum oxide (Al₂O₃) films, for example.

The term “aromatic” generally represents a cyclic, conjugated planar group or moiety with delocalized pi bonding resonance. Example aromatics groups include moieties with 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized pi-electron system. The number of out of plane pi-electrons can correspond to the Huckel rule (4n+2). The point of attachment to the parent structure can be through an aromatic portion of the condensed ring system. Such an aromatic can be unsubstituted or substituted with one or more groups, such as groups described herein for an alkyl or aryl group. Yet other substitution groups can include aliphatic, haloaliphatic, halo, nitrate, cyano, sulfonate, sulfonyl, or others.

The term “aryl” generally represents an aromatic carbocyclic group. Example aryl groups comprise at least five carbon atoms to 15 carbon atoms (C5-15), having a single ring or multiple condensed rings, which condensed rings can or cannot be aromatic provided that the point of attachment to a remaining position of the compounds described herein is through an atom of the aromatic carbocyclic group. Aryl groups can be substituted with one or more groups other than hydrogen, such as aliphatic, heteroaliphatic, aromatic, other functional groups, or any combination thereof. Example aryl groups include benzyl, naphthalene, phenyl, biphenyl, phenoxybenzene, and the like. The term aryl also includes heteroaryl, which is described as a group that contains an aromatic group that has at least one heteroatom incorporated within the ring of the aromatic group. Examples of heteroatoms include nitrogen, oxygen, sulfur, and phosphorus. Likewise, the term non-heteroaryl, which is also included in the term aryl, generally represents a group that contains an aromatic group that does not contain a heteroatom. The aryl group can be substituted or unsubstituted. The aryl group can be substituted with one, two, three, four, or five substituents independently comprising one or more of (1) C1-6 alkanoyl (e.g., —C(O)—R, in which R is C1-6 alkyl); (2) C1-6 alkyl; (3) C1-6 alkoxy (e.g., —O—R, in which R is C1-6 alkyl); (4) C1-6 alkoxy-C1-6 alkyl (e.g., -L-O—R, in which each of L and R is, independently, C1-6 alkyl); (5) C1-6 alkylsulfinyl (e.g., —S(O)—R, in which R is C1-6 alkyl); (6) C1-6 alkylsulfinyl-C1-6 alkyl (e.g., -L-S(O)—R, in which each of L and R is, independently, C1-6 alkyl); (7) C1-6 alkylsulfonyl (e.g., —SO₂—R, in which R is C1-6 alkyl); (8) C1-6 alkylsulfonyl-C1-6 alkyl (e.g., -L-SO₂—R, in which each of L and R is, independently, C1-6 alkyl); (9) aryl; (10) amine (e.g., —NR¹R², where each of R¹ and R² is, independently, selected from hydrogen, aliphatic, heteroaliphatic, haloaliphatic, haloheteroaliphatic, aromatic, as described herein, or any combination thereof, or R¹ and R², taken together with the nitrogen atom to which each are attached, form a heterocyclyl group, as described herein); (11) C1-6 aminoalkyl (e.g., -L¹-NR¹R² or -L²-C(NR¹R²)—(R³)—R⁴, in which L¹ is C1-6 alkyl; L² is a covalent bond or C1-6 alkyl; each of R¹ and R² is, independently, selected from hydrogen, aliphatic, heteroaliphatic, haloaliphatic, haloheteroaliphatic, aromatic, as described herein, or any combination thereof, or R¹ and R², taken together with the nitrogen atom to which each are attached, form a heterocyclyl group, as described herein; and each of R³ and R⁴ is, independently, H or C1-6 alkyl); (12) heteroaryl; (13) C1-6 alkyl-C4- is aryl (e.g., -L-R, in which L is C1-6 alkyl and R is C4-18 aryl); (14) aryloyl (e.g., —C(O)—R, in which R is aryl); (15) azido (e.g., —N³); (16) cyano (e.g., —CN); (17) C1-6 azidoalkyl (e.g., -L-N³, in which L is C1-6 alkyl); (18) aldehyde (e.g., —C(O) H); (19) aldehyde-C1-6 alkyl (e.g., -L-C(O) H, in which L is C1-6 alkyl); (20) C3-8 cycloalkyl; (21) C1-6 alkyl-C3-8 cycloalkyl (e.g., -L-R, in which L is C1-6 alkyl and R is C3-8 cycloalkyl); (22) halo; (23) C1-6 haloalkyl (e.g., -L⁴-X or -L²-C(X) (R⁴)—R², in which L¹ is Ci-6 alkyl; L² is a covalent bond or C1-6 alkyl; X is fluoro, bromo, chloro, or iodo; and each of R¹ and R² is, independently, H or C1-6 alkyl); (24) heterocyclyl (e.g., as described herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C1-6 hydroxyalkyl (e.g., -L⁴-OH or -L²-C(OH)(R¹)—R², in which L¹ is C₁₋₆ alkyl; L² is a covalent bond or alkyl; and each of R¹ and R² is, independently, H or C1-6 alkyl, as defined herein); (29) nitro; (30) C1-6 nitroalkyl (e.g., -L⁴-NO or -L²-C(NO)(R¹)—R², in which L¹ is C1-6 alkyl; L² is a covalent bond or alkyl; and each of R¹ and R² is, independently, H or C1-6 alkyl, as defined herein); (31) N-protected amino; (32) N-protected amino-C1-6 alkyl; (33) oxo (e.g., ═O); (34) C1-6 thioalkoxy (e.g., —S—R, in which R is C₁₋₆ alkyl); (35) thio-Ci-6 alkoxy-C1-6 alkyl (e.g., -L-S—R, in which each of L and R is, independently, C1-6 alkyl); (36) —(CH₂)ᵣCO₂R¹, where r is an integer of from zero to four, and R¹ comprises (a) hydrogen, (b) C1-6 alkyl, (c) C4-18 aryl, or (d) C1-6 alkyl-C4-18 aryl (e.g., -L-R, in which L is C1-6 alkyl and R is C4-18 aryl); (37) —(CH2)ᵣCONR¹R², where r is an integer of from zero to four and where each R¹ and R² independently comprises (a) hydrogen, (b) C1-6 alkyl, (c) C4-18 aryl, or (d) C1-6 alkyl-C4-18 aryl (e.g., -L-R, in which L is C1-6 alkyl and R is C4-18 aryl); (38) —(CH₂)ᵣSO₂R¹, where r is an integer of from zero to four and where R¹ comprises (a) C1-6 alkyl, (b) C4-18 aryl, or (c) C1-6 alkyl-C4-18 aryl (e.g., -L-R, in which L is C1-6 alkyl and R is C4-18 aryl); (39) —(CH₂)ᵣSO₂NR¹R², where r is an integer of from zero to four and where each of R¹ and R² independently comprises (a) hydrogen, (b) C1-6 alkyl, (c) C4-18 aryl, or (d) C1-6 alkyl-C4-18 aryl (e.g., -L-R, in which L is C1-6 alkyl and R is C4-18 aryl); (40) —(CH₂)ᵣNR¹R², where r is an integer of from zero to four and where each of R¹ and R² independently comprises (a) hydrogen, (b) an N-protecting group, (c) C1-6 alkyl, (d) C2-6 alkenyl, (e) C2-6 alkynyl, (f) C4-18 aryl, (g) C1-6 alkyl-C4-18 aryl (e.g., -L-R, in which L is C1-6 alkyl and R is C4-18 aryl), (h) C3-8 cycloalkyl, or (i) C1-6 alkyl-C3-8 cycloalkyl (e.g., -L-R, in which L is C1-6 alkyl and R is C3-8 cycloalkyl), wherein in one example no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); (47) arylalkoxy (e.g., —O-L-R, in which L is alkyl and R is aryl); or (48) —SiR¹R²R³, where each of R¹ and R² and R³ independently comprises (a) hydrogen, (b) halo, such as F, Cl, Br, or I, (c) C1-6 alkyl, (d) C2-6 alkenyl, (e) C2-6 alkynyl, or (f) C1-6 alkoxy (e.g., —OR, in which R is C1-6 alkyl). In particular examples, an unsubstituted aryl group is a C4-18, C4-14, C4-12, C4-10, C6-18, C6-14, C6-12, or C6-10 aryl group.

The term “arylene” generally represents a multivalent (e.g., bivalent) form of an aryl group, as described herein. Example arylene groups include phenylene, naphthylene, biphenylene, triphenylene, diphenyl ether, acenaphthenylene, anthrylene, or phenanthrylene. In some examples, the arylene group is a C4-18, C4-14, C4-12, C4-10, C6-18, C6-14, C6-12, or C6-10 arylene group. The arylene group can be branched or unbranched. The arylene group can also be substituted or unsubstituted. For example, the arylene group can be substituted with one or more substitution groups, as described herein for aryl.

The term “aryleneoxy” generally represents an arylene group, as described herein, attached to the parent molecular group through an oxygen atom.

The term “atomic layer deposition” generally represents a process in which a film (e.g., an oxide film) is formed on a substrate in one or more individual layers by sequentially adsorbing a precursor conformally to the substrate and reacting the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth” and “deposition”, and variants thereof, also may be used to refer to film formation.

The term “barrier layer” generally represents a layer in a substrate that is between a metal layer and a dielectric layer to reduce a rate of metal diffusion into the dielectric layer. The term “barrier layer surface” represents a portion of a substrate surface that comprises an exposed barrier layer.

The term “cycloaliphatic” generally represents an aliphatic group, as described herein, that is cyclic. Such cycloaliphatic groups can be saturated or unsaturated.

The term “cycloalkyl” generally represents a monovalent saturated or unsaturated non-aromatic cyclic hydrocarbon group. Example cycloalkyl groups comprise groups of from three to eight carbons. Examples include cyclopropyl, cyclobutyl, cyclopentyl, cyclohexyl, cycloheptyl, bicyclo[2.2.1. heptyl], and the like. The cycloalkyl group can also be substituted or unsubstituted. For example, the cycloalkyl group can be substituted with one or more groups including those described herein for alkyl.

The term “cycloheteroaliphatic” generally represents a heteroaliphatic group, as defined herein, that is cyclic. Such cycloheteroaliphatic groups can be saturated or unsaturated.

The term “cycloheteroalkyl” generally represents a monovalent saturated or unsaturated non-aromatic cyclic hydrocarbon group of from three to eight carbons and having at least one heteroatom, which can be selected from oxygen, nitrogen, sulfur, silicon, boron, selenium, phosphorous, and oxidized forms thereof within the group. The cycloheteroalkyl group can also be substituted or unsubstituted. For example, the cycloheteroalkyl group can be substituted with one or more groups including those described herein for alkyl.

The term “dielectric surface” generally represents a portion of a substrate surface comprising a dielectric material. The term “dielectric material” generally represents a material that can be polarized by an applied electric field. Examples of dielectric materials include silicon dioxide (SiO₂) including doped SiO₂ (e.g., fluorine-doped and carbon-doped SiO₂), silicon nitride (Si₃N₄), silicon carbide (SiC), silicon oxycarbide (SiOₓC_{y}), silicon oxynitride (SiOₓN_{y}), and silicon carbon nitride (SiCₓN_{y}).

The term “deposit” and variants thereof generally represent a process in which a film (e.g., an oxide film) is formed on a substrate.

The term “flow control hardware” generally represents components configured to place one or more chemical sources in fluid connection with a processing chamber. Flow control hardware can include one or more mass flow controllers and/or valves, for example. Example chemical sources include Si-containing inhibitor sources, metal-containing precursor sources, inert gas sources, and alcohol sources.

The term “flow-over vapor” (FOV) generally represents a flow of a carrier gas over a surface of a liquid chemical to draw and transport chemical vapor with the flow of the carrier gas.

The term “head group” generally represents a portion of a Si-containing inhibitor that is configured to adsorb to a metal surface of a substrate. Examples of head groups include —SiH, —SiX¹, and —SiHX¹X², in which each of X¹ and X² independently comprises hydrogen (H), a halogen, an aliphatic group, a substituted aliphatic group, a cycloaliphatic group, a substituted cycloaliphatic group, an aromatic group, or a substituted aromatic group.

The term “heteroaliphatic” generally represents an aliphatic group, as described herein, including at least one heteroatom. A heteroaliphatic group can have from one to twenty heteroatoms in some examples. The heteroatoms can be independently selected from oxygen, nitrogen, sulfur, silicon, boron, selenium, phosphorous, and oxidized forms thereof.

The terms “heteroalkyl,” “heteroalkenyl,” and “heteroalkynyl,” generally represent an alkyl, alkenyl, or alkynyl group (which can be branched, straight-chain, or cyclic), respectively, as defined herein, including at least one heteroatom. In some examples, a heteroalkyl, heteroalkenyl or heteroalkynyl can have from one to twenty heteroatoms. The heteroatoms can be independently selected from oxygen, nitrogen, sulfur, silicon, boron, selenium, phosphorous, and oxidized forms thereof within the group. The heteroalkyl, heteroalkenyl, and/or heteroalkynyl groups can also be substituted or unsubstituted. For example, the heteroalkyl, heteroalkenyl, and/or heteroalkynyl groups can be substituted with one or more groups including those described herein for alkyl.

The terms “heteroalkylene,” “heteroalkenylene,” and “heteroalkynylene” generally represent an alkylene, alkenylene, or alkynylene group (which can be branched, straight-chain, or cyclic), respectively, as described herein, including at least one heteroatom. In some examples, a “heteroalkylene,” “heteroalkenylene,” and “heteroalkynylene” can have from one to twenty heteroatoms. The heteroatoms can be selected independently from oxygen, nitrogen, sulfur, silicon, boron, selenium, phosphorous, and oxidized forms thereof. The heteroalkylene, heteroalkenylene, and/or heteroalkynylene groups can also be substituted or unsubstituted. For example, the heteroalkylene, heteroalkenylene, and/or heteroalkynylene groups can be substituted with one or more groups including those described herein for alkyl.

The term “heterocyclyl” generally represents a 3-, 4-, 5-, 6- or 7-membered ring, unless otherwise specified, containing at least one heteroatom. In some examples, a heterocyclyl can have one, two, three, or four non-carbon heteroatoms (e.g., nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings comprising one or more of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodi oxanyl, benzodioxocinyl, benzodi oxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotri azolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl, benzylsultimyl, bipyrazinyl, bipyridinyl, carbazolyl (e.g., 4H-carbazolyl), carbolinyl (e.g., P-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarb azolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, di oxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., IH-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothi oxolyl, naphthotri azolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotri azolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, or the like, and/or modified forms thereof (e.g., including one or more oxo and/or amino) or salts thereof. The heterocyclyl group can be substituted or unsubstituted. For example, the heterocyclyl group can be substituted with one or more substitution groups, as described herein for aryl.

The term “heterocyclyldiyl” generally represents a bivalent form of a heterocyclyl group, as described herein. In one instance, the heterocyclyldiyl is formed by removing a hydrogen from a heterocyclyl group. Example heterocyclyldiyl groups include piperdylidene, quinolinediyl, etc. The heterocyclyldiyl group can also be substituted or unsubstituted. For example, the heterocyclyldiyl group can be substituted with one or more substitution groups, as described herein for heterocyclyl.

The term “inert gas” generally represents a gas that is not transformed into chemically reactive species in a plasma. An inert gas can be ionized in a plasma to sputter a surface exposed to ions of the inert gas.

The term “inert gas plasma pre-treatment” generally represents a process in which a substrate is exposed to a plasma comprising an inert gas as a majority component. The term “majority component” generally represents a gas with a highest partial pressure in an environment comprising one or more gases.

The term “ligand” generally represents a functional group (ionic or molecular) that is bonded to a metal or metalloid species by coordinate bonding.

The term “metal-containing precursor” generally represents compound that includes one or more metal atoms for forming a metal-containing thin film. Examples of metal-containing precursors include aluminum-containing precursors and hafnium-containing precursors. In some instances, metalloids, such as boron, are also suitable for use as a metal-containing precursor.

The term “metal surface” generally represents a portion of a substrate surface that comprises one or more unoxidized metals.

The term “organic ligand” generally represents a compound containing at least one carbon atom and which is bound to a silicon atom of the silicon-containing inhibitor.

The term “organic moiety” generally represents a portion of a silicon-containing inhibitor that comprises an organic functional group. Examples of organic moieties include aliphatic groups, substituted aliphatic groups, heteroaliphatic groups, substituted heteroaliphatic groups, cycloaliphatic groups, substituted cycloaliphatic groups, cycloheteroaliphatic groups, substituted cycloheteroaliphatic groups, aromatic groups, and substituted aromatic groups.

The term “plasma” generally represents a gas comprising cations and free electrons. A plasma can be used to generate reactive chemical species from a precursor molecule introduced into the plasma.

The term “plasma generator” refers generally to hardware configured to form a plasma for processing a substrate in a processing chamber. The term “capacitively coupled plasma” refers generally to a plasma in which energy for the plasma is supplied by an electric field generated between electrodes. The term “inductively coupled plasma” refers generally to a plasma in which energy for the plasma is supplied by electric currents produced by electromagnetic induction.

The term “pre-treating” and variants thereof generally represent subjecting a substrate to a process before exposing the substrate to a silicon-containing inhibitor.

The term “processing chamber” generally represents an enclosure in which chemical and/or physical processes are performed on substrates. The pressure, temperature and atmospheric composition within a processing chamber are controllable to perform chemical and/or physical processes.

The term “silicon-containing inhibitor” generally represents a silicon-containing compound that can be introduced into a processing chamber, that can be deposited selectively on a metal surface of a substrate while not adsorbing to a dielectric surface, and that inhibits growth of an oxide film. The term “inhibitor” is used herein to represent an inhibitor molecule introduced into a processing chamber, reactive inhibitor species formed in a plasma, and adsorbed inhibitor on a substrate surface.

The term “substrate” generally represents any object on which a film can be deposited.

The term “substrate holder” generally represents any structure configured to support a substrate in a processing chamber. Examples comprise pedestals, electrostatic chuck pedestals, and showerhead pedestals used for backside deposition processes.

The term “tail group” generally represents an organic ligand portion of a silicon-containing inhibitor that extends outward from the silicon atom.

As introduced above, some integrated circuit fabrication processes include forming metal lines in a dielectric material. The metal lines form conductive paths within an integrated circuit. Formation of such embedded metal lines requires patterning and etching of the dielectric material to form vias and trenches, followed by filling of these vias and trenches with one or more metals (e.g., tungsten (W), molybdenum (Mo), ruthenium (Ru), copper (Cu), Cu alloys, tantalum (Ta), and/or cobalt (Co)). Such metals can be deposited by electroplating, for example.

In some examples, a metal line can include a plurality of different metals. As one such example, a copper metal line can be surrounded by a cap made of cobalt or other metal. In additional a barrier layer can be provided around the cap to help reduce a risk of metal diffusion into a surrounding dielectric material. Example barrier layers can include tantalum, iridium and/or rhodium. As a more specific example, a barrier layer can be formed from tantalum nitride.

In some integrated circuit manufacturing processes, after forming a first metal line in a first dielectric layer, a second dielectric layer can then be deposited and patterned. Then, additional metal features can be formed in the second dielectric layer. Such additional metal features can be positioned to contact the first metal line. However, it can be technologically challenging to selectively deposit dielectric material in accurate locations to form the second dielectric layer. Inaccurate deposition of the dielectric material can lead to edge placement errors. An edge placement error is an error in which an edge of the additional metal feature is offset from an intended position. Edge placement errors can cause unwanted capacitance between two conductive features that are not spaced correctly. This can increase resistive-capacitive (RC) delay. In some cases, edge placement error can even lead to formation of a short between conductive features. Inaccurate deposition also can lead to so-called “tiger tooth” defects. The term “tiger tooth” refers to the shape of the defect, which manifests as a jagged edge shape. Tiger tooth defects also can increase RC delay and impact device performance. These errors can increase the difficulty of further downscaling of semiconductor devices.

To help avoid such defects, a selective deposition process can be used. In a selective deposition process, a film is deposited on some substrate surfaces but not others based upon a chemical selectivity. As a more specific example, in some integrated circuit fabrication processes, an aluminum oxide (Al₂O₃) film can be used as an intermetal dielectric. As described below, Al₂O₃ can be selectively deposited on a dielectric material and not on a neighboring metal material. This allows accurate placement of the Al₂O₃ layer edge without complex lithographic patterning processes. However, Al₂O₃ has a higher dielectric constant (K) than some other materials, such as silicon dioxide (SiO₂). This can lead to an RC penalty in a resulting integrated circuit when using Al₂O₃ as dielectric material between conductive lines compared to SiO₂ or other materials with a lower k than Al₂O₃.

Accordingly, examples are disclosed that relate to selectively forming a layer of silicon oxide (SiO₂) over a dielectric surface of a substrate comprising a metal surface and the dielectric surface. Briefly, the substrate is exposed to a silicon (Si)-containing inhibitor to selectively adsorb the Si-containing inhibitor to the metal surface of the substrate. As described in more detail below, the Si-containing inhibitor adsorbs to metal substrate surfaces, but not to dielectric surfaces. Next, a catalytic layer is formed at least in part by exposing the substrate to a metal-containing precursor to adsorb the metal-containing precursor to the dielectric surface. The Si-containing inhibitor inhibits adsorption of the metal-containing precursor to the metal surface. The substrate is then exposed to a silanol-based silicon oxide precursor. The catalytic layer catalyzes a conversion of the silanol-based silicon oxide precursor to SiO₂. The selective adsorption of the Si-containing inhibitor on the metal surface helps to avoid errors and defects, such as edge placement error and tiger tooth defects. As a result, relatively smaller integrated circuit elements can be fabricated with similar accuracy to relatively larger integrated circuit elements using a same process. Furthermore, the SiO₂ has a lower K than Al₂O₃. This can reduce RC delay relative to integrated circuit devices comprising Al₂O₃.

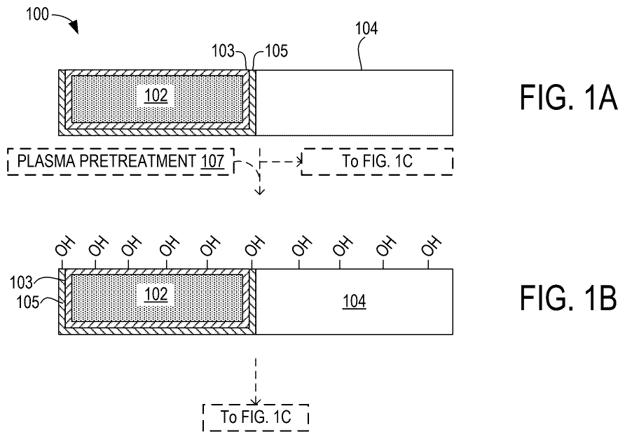

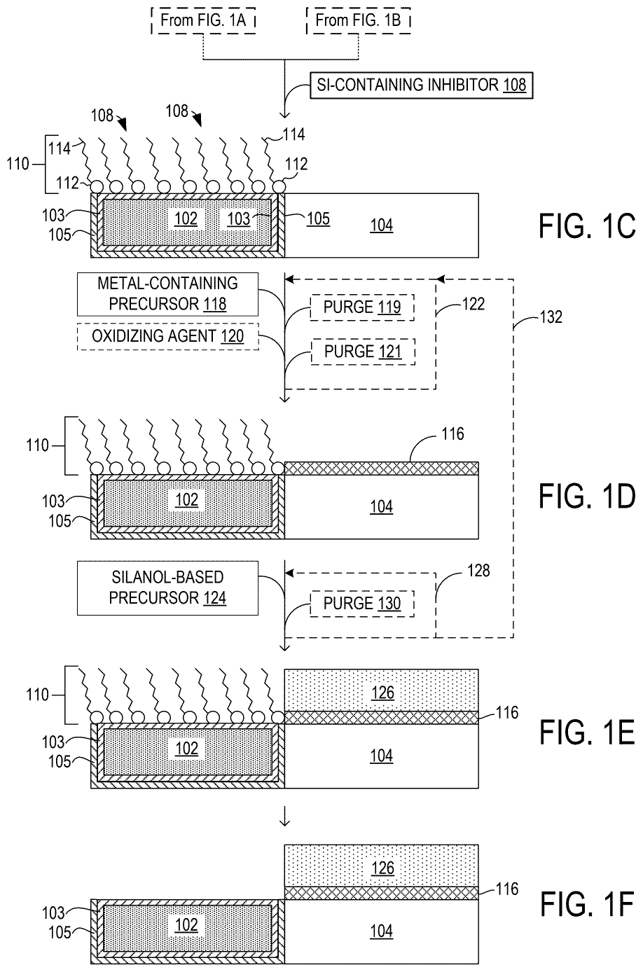

FIGS. 1A-1F schematically show a cross-sectional view of a substrate 100 at various stages in a SiO₂ deposition process. Referring first to FIG. 1A, the substrate 100 comprises a metal surface 102 and a dielectric surface 104. Examples of suitable metals for metal surface 102 include Co, Cu, W, Ru, rhodium (Rh), iridium (Ir), tantalum (Ta), titanium (Ti), hafnium (Hf), zirconium (Zr), Mo, as well as combinations thereof and/or doped forms thereof.

The metal surface 102 is at least partially surrounded by a protective cap 103 and a barrier layer 105. In the example illustrated in FIG. 1B, the protective cap 103 covers the metal surface 102. In some such examples, the silicon-containing inhibitor can bind to the protective cap 103 rather than directly to the underlying metal surface 102. In other examples, at least a portion of the protective cap 103 can be removed (e.g., by abrasion) to expose the metal surface 102.

The protective cap 103 can comprise Co. The barrier layer 105 can comprise Ta or tantalum nitride (TaN). In other examples, other suitable materials can be used for the protective cap 103 and the barrier layer 105. Further examples of suitable materials include Rh and Ir.

The dielectric surface 104 can comprise any suitable dielectric material. Examples include SiO₂, doped SiO₂ (e.g., carbon-doped or fluorine-doped SiO₂), silicon nitride (Si₃N₄), silicon carbide (SiC), silicon oxycarbide (SiOₓC_{y}), silicon oxynitride (SiOₓN_{y}), and silicon carbon nitride (SiCₓN_{y}). While silicon carbide can be considered a semiconductor, the band gap of silicon carbide may be sufficiently high for silicon carbide to be used as a dielectric material in some applications. Metal surface 102 and dielectric surface 104 may represent layers that are formed over other underlying layers. Such underlying layers are of arbitrary composition, and are not shown in FIGS. 1A-1F for the purpose of clarity.

Next, as illustrated in FIG. 1B, the substrate 100 is optionally exposed to a plasma pre-treatment 107.

The Si-containing inhibitor can have less affinity for Ta or TaN in barrier layer 105 than for Co of the protective cap 103 or Cu of the metal surface 102. Thus, a plasma pre-treatment 107 comprising oxygen (O₂) and hydrogen (H₂) can be used to form hydroxyl radicals. The hydroxyl radicals adsorb at least to barrier layer 105. This can enable the Si-containing inhibitor to adsorb to the barrier layer 105. This helps prevents horizontal growth, or “mushrooming”, of the SiO₂ over the barrier layer 105. In some examples, the plasma further comprises an inert gas. Examples of inert gases include He, Ne, Ar, Kr, and Xe. In other examples, the plasma treatment can include the use of a plasma comprising ammonia (NH₃) gas. The plasma pre-treatment 107 can be performed for any suitable length of time. Examples include times within a range of 1 second to 90 seconds. In other examples, a plasma pre-treatment can use a different chemistry than O₂ and H₂, or can be omitted.

As a more specific example, a two-step plasma pre-treatment can be used. In such a two-step pre-treatment, an ammonia plasma is applied to the substrate, followed by an oxygen/hydrogen plasma. The ammonia plasma can help to reduce nucleation delay of a dielectric material layer on a dielectric surface of the substrate by making the dielectric surface more hydrophilic. The hydrogen/oxygen plasma can hydroxylate the surface of the barrier layer. The term “hydroxylate” and variants thereof generally represents the formation of hydroxyl (—OH) groups on a surface.

Referring next to FIG. 1C, the Si-containing inhibitor 108 comprises a head group 112 and a tail group 114. The head group 112 is located proximate to the metal surface 102. In other examples, at least some molecules of the Si-containing inhibitor 108 are oriented in a different direction. For example, the inhibitor layer 110 can include an ordered layer with precise head group orientation to the metal surface 102 and/or a disordered layer with some head groups oriented in different directions.

In some examples, the inhibitor layer 110 is a monolayer. The monolayer comprises a single layer of the Si-containing inhibitor molecules. In other examples, the inhibitor layer 110 is a multilayer. The multilayer includes more than one layer of the Si-containing inhibitor molecules. Within the multilayer, each layer can be oriented in any suitable manner. In some such examples, the multilayer can comprise a first layer in which head groups 112 are primarily oriented towards the metal surface 102. A second layer disposed above the second layer can have its tail groups 114 oriented towards the tail groups 114 of the first layer. Any suitable configuration of layers and Si-containing inhibitors can be used. This can result in faster or more stable self-assembly of the multilayer relative to a single-layer structure.

The Si-containing inhibitor 108 comprises at least one Si atom and one or more organic ligands. In some examples, the Si-containing inhibitor 108 includes at least one Si—H bond or group. In other examples, the Si-containing inhibitor 108 includes at least three Si—H bonds and an organic moiety (e.g., RSiH₃, in which R is the organic moiety).

In some examples, the head group 112 of the Si-containing inhibitor 108 comprises a Si atom and the tail group 114 comprises an organic moiety. In other examples, the head group 112 comprises —SiH or —SiX¹ or —SiHX¹X², in which each of X¹ and X² independently comprises hydrogen (H), a halogen, an aliphatic group, a substituted aliphatic group, a cycloaliphatic group, a substituted cycloaliphatic group, an aromatic group, or a substituted aromatic group. In some more specific examples, each of X¹ and X² is, independently, selected from H, fluorine (F), chlorine (Cl), bromine (Br), or iodine (I). In other more specific examples, each of X¹ and X² is, independently, selected from H, a halogen, a 6-carbon alkyl group, or a substituted 6-carbon alkyl group. In further examples, the head group can have any other suitable composition.

In some examples, the organic moiety of the tail group comprises an aliphatic group, a substituted aliphatic group, a heteroaliphatic group, a substituted heteroaliphatic group, a cycloaliphatic group, a substituted cycloaliphatic group, a cycloheteroaliphatic group, a substituted cycloheteroaliphatic group, an aromatic group, or a substituted aromatic group. In other examples, the organic moiety comprises an alkyl group, a substituted alkyl group, an alkenyl group, a substituted alkenyl group, an alkynyl group, a substituted alkynyl group, a heteroalkyl group, a substituted heteroalkyl group, a heteroalkenyl group, a substituted heteroalkenyl group, a heteroalkynyl group, a substituted heteroalkynyl group, a cycloalkyl group, a substituted cycloalkyl group, a cycloheteroalkyl group, a substituted cycloheteroalkyl group, an aryl group, a substituted aryl group, a heterocyclyl group, or a substituted heterocyclyl group. In some more specific examples, the organic moiety comprises a branched-chain hydrocarbon. In other examples, the organic moiety comprises an alkyl group having one or more halogen substitutions (e.g., one or more fluorine substitutions).

In further examples, the organic moiety of the tail group comprises-X-L-Z. X comprises a covalent bond, an alkylene group, a substituted alkylene group, an alkenylene group, a substituted alkenylene group, an alkynylene group, a substituted alkynylene group, an alkyleneoxy group, a substituted alkyleneoxy group, a heteroalkylene group, a substituted heteroalkylene group, a heteroalkenylene group, a substituted heteroalkenylene group, a heteroalkynylene group, a substituted heteroalkynylene group, an arylene group, a substituted arylene group, an aryleneoxy group, a substituted aryleneoxy group, a heterocyclyl diyl group, or a substituted heterocyclyl diyl group. L comprises a covalent bond, —CR¹R²—, —CR¹═CR²—, —NR¹—, —C(O)—, —C(O)NR¹—, —NR¹C(O)—, —C(O)O—, —OC(O)—, —S—, or —O—. Each of R¹ and R² comprises, independently, H, an alkyl group, or a substituted alkyl group. Z comprises H, an alkyl group, a substituted alkyl group, an alkenyl group, a substituted alkenyl group, an alkynyl group, a substituted alkynyl group, a heteroalkyl group, a substituted heteroalkyl group, a heteroalkenyl group, a substituted heteroalkenyl group, a heteroalkynyl group, a substituted heteroalkynyl group, an aryl group, a substituted aryl group, a heterocyclyl group, or a substituted heterocyclyl group. In other examples, X comprises an alkylene group or a substituted alkylene group. L comprises a covalent bond, —CR¹R²—, —CR¹—CR²—, —NR¹—, —C(O)—, —C(O)NR¹—, —NR¹C(O)—, —C(O)O—, —OC(O)—, —S—, or —O—. Each of R¹ and R² comprises, independently, H, a 6-carbon alkyl group, or a substituted 6-carbon alkyl group. Z comprises H, an alkyl group, or a substituted alkyl group.

In some examples, the organic moiety of the tail group comprises 6 to 26 carbon atoms (e.g., 6 to 24, 6 to 20, 6 to 18, 8 to 26, 8 to 24, 8 to 20, 8 to 18, 10 to 26, 10 to 24, 10 to 20, or 10 to 18 carbon atoms). The carbon atoms can form a linear chain, a branched chain, or a cyclic group. In some more specific examples, the organic moiety comprises a 26-carbon alkyl group, a substituted 26-carbon alkyl group, a 26-carbon alkenyl group, a substituted 26-carbon alkenyl group, a 26-carbon alkynyl group, a substituted 26-carbon alkynyl group, a 26-carbon heteroalkyl group, a substituted 26-carbon heteroalkyl group, a 26-carbon heteroalkenyl group, a substituted 26-carbon heteroalkenyl group, a 26-carbon heteroalkynyl group, a substituted 26-carbon heteroalkynyl group, a 26-carbon cycloalkyl group, a substituted 26-carbon cycloalkyl group, a 26-carbon cycloheteroalkyl group, a substituted 26-carbon cycloheteroalkyl group, a 26-carbon aryl group, a substituted 26-carbon aryl group, a 26-carbon heterocyclyl group, or a substituted 26-carbon heterocyclyl group.

In some more specific examples, the Si-containing inhibitor 108 can comprise n-octadecylsilane (C₁₈H₄₀Si), tridecylsilane (C₁₃H₃₀Si), dodecylsilane (C₁₂H₂₈Si), undecylsilane (C₁₁H₂₆Si), decylsilane (C₁₀H₂₄Si), decan-4-ylsilane (C₁₀H₂₄Si), nonylsilane (C₉H₂₂Si), nonan-4-ylsilane (C₉H₂₂Si), octan-2-ylsilane (C₈H₂₀Si), octylsilane (C₈H₂₀Si), heptylsilane (C₇H₁₈Si), heptan-4-ylsilane (C₇H₁₈Si), (tridecafluoro-1,1,2,2-tetra-hydrooctyl) silane (C₈H₇F₁₃Si), or 10-undecenylsilane (C₁₁H₂₄Si).

Properties of the inhibitor layer 110 can be characterized by its mass change, which can indicate the number of intact or cleaved inhibitor molecules; its water contact angle (WCA), which can indicate the density or packing of the layer(s); and/or its C—H bending or stretching modes using Fourier-transform infrared spectroscopy (FTIR), can indicate the density or packing of the layer(s). In some examples, the inhibitor layer is characterized by a WCA of more than about 100° or from about 100° to 120°.

The Si-containing inhibitor 108 can be introduced to the metal surface 102 under any suitable process conditions. In some examples, the Si-containing inhibitor is provided by vapor soaking. In some such examples, the Si-containing inhibitor can be provided in a processing chamber with a dose time of about 5 seconds to 600 seconds. The Si-containing inhibitor can be provided at a substrate temperature within a range of about 50° C. to 400° C. in some examples. In some more specific examples, the Si-containing inhibitor can be provided at a substrate temperature within a range of 50° C. to 100° C. Further, in some examples, the Si-containing inhibitor can be provided at a pressure of about 5 Torr to 10 Torr. In some examples, the Si-containing inhibitor is provided with an inert carrier gas (e.g., nitrogen (N₂), helium (He), neon (Ne), argon (Ar), krypton (Kr), or xenon (Xe)). In other examples, an inert gas is omitted. Delivery of the Si-containing inhibitor 108 can be continuous or in pulses.

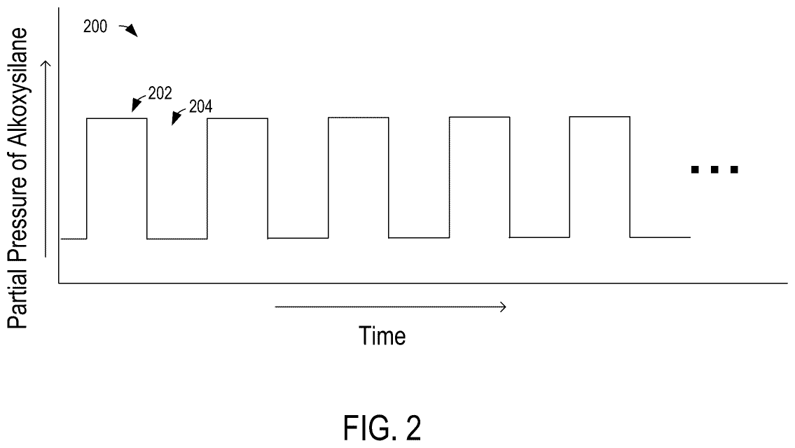

Process conditions can be adjusted based upon the composition and chemical characteristics of the Si-containing inhibitor and the metal oxide to be deposited. For example, adsorption of the Si-containing inhibitor can be characterized by mass change and/or a WCA at various pedestal temperatures (e.g., from 120° C. to 300° C.) or pressures (e.g., from 5 to 10 Torr). In some examples, a WCA of about 100° or more can be obtained. Other examples can include chemical characterization of the inhibitor layer 110, such as by FTIR, transmission electron microscopy (TEM), cross-sectional transmission electron microscopy (XTEM), and/or energy-dispersive X-ray spectroscopy (EDS). Additional details regarding processing conditions are described in more detail below with reference to FIGS. 2-5.

Next, as shown in FIG. 1D, a catalytic layer 116 is formed on the dielectric surface 104. The formation of the catalytic layer 116 comprises exposing the substrate 100 to a metal-containing precursor 118. The metal-containing precursor 118 is introduced into a processing chamber in which the substrate 100 is located. The metal-containing precursor 118 adsorbs to the dielectric surface 104. The Si-containing inhibitor 108 inhibits the metal-containing precursor 118 from adsorbing to the metal surface 102.

As described below, the metal-containing precursor 118 acts as a catalyst in the formation of a SiO₂ layer. In some examples, the adsorbed metal-containing precursor 118 is used as a catalyst, without further processing. In other examples, the metal-containing precursor 118 is further processed to convert the metal-containing precursor 118 into the catalytic layer 116. For example, an aluminum (Al)-containing precursor can be converted to an Al₂O₃ film. In such examples, a plurality of layers of the Al₂O₃ film can be formed using atomic layer deposition.

As introduced above, in some examples, the metal-containing precursor comprises an Al-containing precursor. Examples of suitable Al-containing precursors can include methyl aluminum propoxide (MeAl(OPr)₂), methyl aluminum isopropoxide (MeAl(OⁱPr)₂), methyl aluminum butoxide (MeAl(OBu)₂), methyl aluminum t-butoxide (MeAl(O^{t}Bu)₂), methyl aluminum ethoxide (MeAl(OEt)₂), dimethyl aluminum propoxide (Me₂Al(OPr)), dimethyl aluminum isopropoxide (Me₂Al(OⁱPr)), dimethyl aluminum butoxide (Me₂Al(OBu)), dimethyl aluminum t-butoxide (Me₂Al(O^{t}Bu)), dimethyl aluminum ethoxide (Me₂Al(OEt)), ethyl aluminum propoxide (EtAl(OPr)₂), ethyl aluminum isopropoxide (EtAl(OⁱPr)₂), ethyl aluminum butoxide (EtAl(OBu)₂), ethyl aluminum t-butoxide (EtAl(O^{t}Bu)₂), ethyl aluminum ethoxide (EtAl(OEt)₂), diethyl aluminum propoxide (Et₂Al(OPr)), diethyl aluminum isopropoxide (Et₂Al(OⁱPr)), diethyl aluminum butoxide (Et₂Al(OBu)), diethyl aluminum t-butoxide (Et₂Al(O^{t}Bu)), diethyl aluminum ethoxide (Et₂Al(OEt)), propyl aluminum propoxide (PrAl(OPr)₂), propyl aluminum isopropoxide (PrAl(OⁱPr)₂), propyl aluminum butoxide (PrAl(OBu)₂), propyl aluminum t-butoxide (PrAl(O^{t}Bu)₂), propyl aluminum ethoxide (PrAl(OEt)₂), dipropyl aluminum propoxide (Pr₂Al(OPr)), dipropyl aluminum isopropoxide (Pr₂Al(OⁱPr)), dipropyl aluminum butoxide (Pr₂Al(OBu)), dipropyl aluminum t-butoxide (Pr₂Al(O^{t}Bu)), and dipropyl aluminum ethoxide (Pr₂Al(OEt)). It will be appreciated that the Al-containing precursor 118 can include any other suitable ligand(s) than the ligands of the example precursors listed above. Other examples of suitable ligands include hydrocarbons, alkoxides, and/or substituted alkyl ligands. In yet other examples, the metal-containing precursor comprises any other suitable metal, such as hafnium. In other instances, metalloids (such as boron) can serve as the metal-containing precursor to form the catalytic layer 116.

The use of relatively large, bulky ligands in the metal-containing precursor 118 (e.g., larger than the methyl ligands of trimethyl aluminum (TMA)) results in steric hindrance at the inhibitor layer 110. As a result, the metal-containing precursor 118 is blocked from the metal surface 102. The use of smaller metal-containing precursors (e.g., TMA) can result in less-selective deposition as these smaller metal-containing precursors encounter less steric hindrance from the inhibitor layer. Furthermore, in some examples, the metal-containing precursor 118 has a dipole moment. As such, the metal-containing precursor 118 can be repelled by hydrophobic tail groups 114 of the Si-containing inhibitor 108. However, the steric effects and/or polarity of the metal-containing precursor 118 do not prevent (i) adsorption of the metal-containing precursor 118 at the dielectric surface 104, and/or (ii) oxidation of the metal-containing precursor 118 as described in more detail below.

As mentioned above, in some examples, the adsorbed metal-containing precursor 118 is used as a catalytic layer 116 without further processing. In other examples, the metal-containing precursor is oxidized (e.g., Al is converted to Al₂O₃). The Al₂O₃ then is used as catalytic layer 116. In such examples, forming the catalytic layer 116 further comprises introducing an oxidizing agent 120 into the processing chamber to thereby oxidize the metal-containing precursor 118 and form an Al₂O₃ layer on the dielectric surface 104. The processing chamber is optionally purged at 119 before the oxidizing agent 120 is introduced. The chamber is optionally purged again at 121 after the oxidizing agent 120 is introduced into the processing chamber. In some examples, the adsorption/purge/oxidation/purge sequence can be repeated, as indicated by arrow 122, to grow the metal oxide film layer by layer using atomic layer deposition (ALD).

In some examples, the oxidizing agent 120 comprises one or more of water or an alcohol. Some examples of suitable alcohols can include isopropyl alcohol, 1-butyl alcohol, 2-butyl alcohol, or t-butyl alcohol. The alcohol reacts with the Al-containing precursor 118 despite steric hindrance from the alcohol and/or the Al-containing precursor 118. This is facilitated by the polarity of both the alcohol and the Al-containing precursor.

Next, the substrate 100 is exposed to a silanol-based silicon oxide precursor 124. The catalytic layer 116 catalyzes a conversion of the silanol-based silicon oxide precursor 124 to SiO₂ layer 126. The silanol-based silicon oxide precursor 124 binds to a metal-containing site in the catalytic layer 116. Without wishing to be bound by theory, an additional silanol-based silicon oxide precursor molecule may also bind to the same metal-containing site. Binding of the additional silanol-based silicon oxide precursor molecule may displace a previously bound silanol-based silicon oxide precursor from the metal-containing site, which may then substitute itself for one of the alkoxy moieties on the additional silanol-based silicon oxide precursor. Cross-linking of polymerized silanol-based silicon oxide precursor chains yields SiO₂. In this manner, the metal-containing site catalyzes conversion of the silanol-based silicon oxide precursor 124 to SiO₂ from the bottom-up.

In some examples, each alkoxy group of the silanol-based silicon oxide precursor comprises one to seven carbon atoms. It will be appreciated that in examples where the silanol-based silicon oxide precursor comprises two or more alkoxy substituents, such substituents can all be identical, or some substituents can be different from one another. In other examples, larger alkoxy groups can be used. The alkoxy groups can comprise linear alkyl moieties groups, branched alkyl moieties, and/or cyclic alkyl moieties. Further, the alkoxy groups can comprise alkenyl and/or alkynyl groups in some examples. The alkoxy groups can be unsubstituted or substituted in various examples.

In some more specific examples, the silanol-based silicon oxide precursor 124 comprises one or more of mono(tert-pentoxy)silanol, bis(tert-pentoxy)silanol, tris(tert-pentoxy)silanol, mono(tert-butoxy)silanol, bis(tert-butoxy)silanol, tris(tert-butoxy)silanol, mono(isopropoxy)silanol, bis(isopropoxy)silanol, or tris(isopropoxy)silanol. It will also be appreciated that the silanol-based silicon oxide precursor 124 can include any other suitable substituents than the substituents of the example precursors listed above. Other example substituents include aromatic and antiaromatic groups.

In some examples, exposing the substrate 100 to the silanol-based silicon oxide precursor 124 comprises introducing the silanol-based silicon oxide precursor 124 into the processing chamber in one or more pulses 128. In each pulse 128, the silanol-based silicon oxide precursor 124 is introduced into the processing chamber. The processing chamber is then purged as indicated at 130 before introducing another pulse 128 of the silanol-based silicon oxide precursor 124. As SiO₂ layer 126 grows, additional molecules of the silanol-based silicon oxide precursor 124 diffuse through the SiO₂ layer 126 to reach the catalytic layer 116. Cross-linking and thickening of the SiO₂ layer 126 can make it increasingly difficult for the additional molecules of the silanol-based silicon oxide precursor 124 to reach the catalytic layer 116. Providing the silanol-based silicon oxide precursor 124 in the one or more pulses 128 can help to balance diffusion, growth and cross-linking to enable controlled growth of the SiO₂ layer 126 on the catalytic layer 116.

Example treatment conditions include a treatment time in a range of 5 seconds to 1 hour, a substrate temperature of about 200° C. to 400° C., and/or a pressure of about 3 to 18 torr. Such treatment conditions can balance diffusion, growth and cross-linking of the SiO₂ layer 126 to achieve controlled growth of the SiO₂ 126. In other examples, other suitable conditions than these can be used to form the SiO₂ layer 126.

FIG. 2 schematically shows an example timing diagram 200 illustrating exposure of the substrate 100 to a silanol-based silicon oxide precursor 124. The silanol-based silicon oxide precursor is introduced into the processing chamber in a series of pulses 202 in which the silanol-based silicon oxide precursor has a first, higher partial pressure. After performing a pulse of the alkoxy silane, the partial pressure is decreased in a purging step 204. The purging steps allows silanol-based silicon oxide precursor from prior pulses to diffuse through SiO₂ layer 126 that has already grown to reach the catalyst layer 116. The pulses can have any suitable duration and flow. Example durations for each pulse include times in a range of 0.2 seconds-600 seconds. Example durations for each purge include times in a range of 0.1 seconds to 60 seconds. In other examples, durations outside of these ranges can be used. While the silanol-based silicon oxide precursor partial pressure is shown as a square wave in the schematic depiction of claim 2, the partial pressure increase and partial pressure decrease of each pulse can have a sloped and/or curved shape in practice.

As indicated at 132, in some examples, the catalytic layer 116 is reapplied at an intermediate time after the substrate 100 is exposed to the silanol-based silicon oxide precursor 124. As described above, as the thickness of the SiO₂ layer 126 increases, a distance between an incoming silanol-based silicon oxide precursor 124 and the catalytic layer 116 increases. This slows the conversion of the silanol-based silicon oxide precursor 124 to the SiO₂ layer 126 due to the SiO₂ blocking diffusion of the silanol-based silicon oxide precursor to the catalyst layer 116. In some examples, the SiO₂ layer 126 can form a layer up to about 150 angstroms thick before another catalyst layer is deposited on the SiO₂ layer 126. Reapplication of the catalytic layer 116 on top of the SiO₂ layer 126 enables additional growth of layer of the SiO₂ layer 126.

Referring next to FIG. 1F, the substrate 100 is post-treated to remove the inhibitor layer 110 from the metal surface 102 after the catalytic layer 116 is deposited on the dielectric surface 104. Such post-treatment can include a plasma treatment, a wet etch treatment, a dry etch treatment, or combinations of two or more thereof. As more specific examples, a post-treatment can include a plasma treatment using hydrogen (H₂) gas or ammonia (NH₃) gas, optionally with one or more inert carrier gases (e.g., He, Ne, Ar, Kr, Xe). Such post-treatment can additionally or alternatively include using a plasma treatment (e.g., a H₂/He plasma) to remove carbon from the SiO₂ layer 126. The plasma can be an inductively coupled plasma or a capacitively coupled plasma. In some examples, post-treatment conditions include a treatment time in a range of 5-35 seconds and/or a substrate temperature of about 200° C. to 400° C. in other examples, other suitable conditions than these can be used.

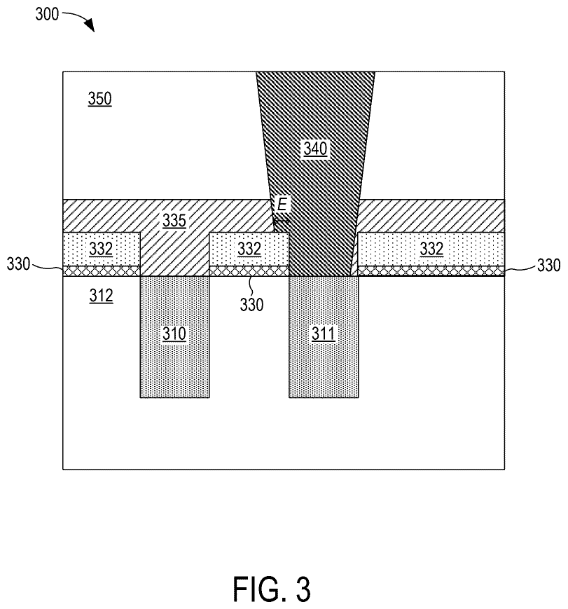

FIG. 3 schematically shows an example stack 300 of film layers formed by the processes described herein. As illustrated in FIG. 3, the stack 300 includes a dielectric layer 312 comprising metal lines 310, 311. Details of metal lines 310, 311, such as cap layers and barrier layers, are omitted from FIG. 3 for simplicity. With the processes herein, the metal lines 310, 311 can serve as a region upon which an inhibitor layer can be deposited. Further, the dielectric material 312 can serve as a region upon which a catalytic layer 330 can be deposited. A SiO₂ layer 332 is deposited on at least a portion of the surface of the catalytic layer 330. Further processing steps form a metal via 340 that is electrically connected to metal line 311. The further processing steps also form a cap layer 335 and an additional dielectric layer 350.

The distance between an intended and actual position on the edge of the metal via 340 can be characterized by an edge placement error E, as indicated in FIG. 3. As described above, the methods and processes described herein can contain the edge placement error E within a tolerance that prevents the metal via 340 from being placed too close to other metal lines, such as metal line 310. This can help to avoid unwanted capacitance, short-circuiting, and possibly other issues.

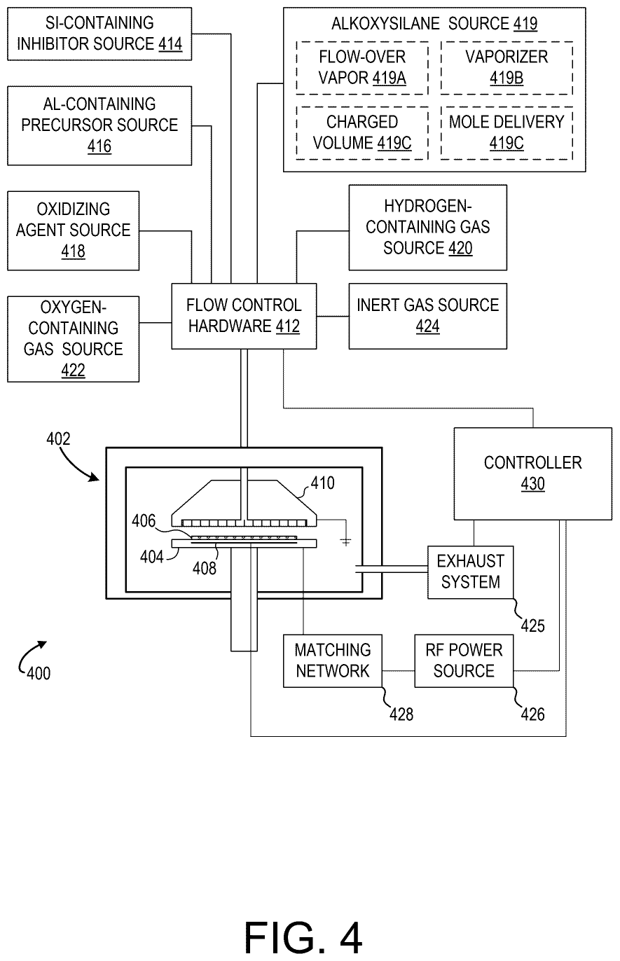

FIG. 4 shows a schematic view of an example processing tool 400 for depositing a SiO₂ layer as disclosed. The processing tool 400 is an example of a processing tool that can implement the methods described above with reference to FIGS. 1A-1F. More particularly, the processing tool 400 can be used to deposit a Si-containing inhibitor, a catalytic layer, and/or a SiO₂ layer. In other examples, deposition of the Si-containing inhibitor, the catalytic layer, and/or the SiO₂ layer can be performed using separate tools.

The processing tool 400 comprises a processing chamber 402 and a substrate support 404 within the processing chamber. The substrate support 404 is configured to support a substrate 406 disposed within the processing chamber 402. The substrate support 404 can comprise a pedestal, an electrostatic chuck pedestal, or any other suitable structure. The substrate support 404 comprises a substrate heater 408.

The processing tool 400 further comprises a showerhead 410. In other examples, a processing tool can comprise a nozzle or other apparatus for introducing gas into processing chamber 402, as opposed to or in addition to a showerhead. The processing tool 400 further comprises flow control hardware 412. The flow control hardware 412 connects processing gas source(s) to the processing chamber. In the depicted example, the flow control hardware 412 connects a Si-containing inhibitor source 414, a metal-containing precursor source 416, an oxidizing agent source 418, a silanol-based silicon oxide precursor source 419, an optional hydrogen-containing gas source 420, an optional oxygen-containing gas source 422, and an inert gas source 424 to the processing chamber. The flow control hardware 412 can include any suitable components. Examples include mass flow controllers, valves, and conduits.

The Si-containing inhibitor source 414 comprises any suitable silicon-containing inhibitor for selectively adsorbing to a metal surface. Examples include the Si-containing inhibitors listed above. In some examples, the Si-containing inhibitor source contains a Si-containing inhibitor that is in a condensed phase at standard pressure and temperature. In such examples, the Si-containing inhibitor source 414 can comprise a flow-over-vapor delivery system, a vaporizer delivery system, charged volume delivery system, a mole delivery device, or other suitable delivery system to volatilize the condensed phase Si-containing inhibitor.

The metal-containing precursor source 416 comprises a volatile or volatilizable metal-containing precursor that adsorbs to a substrate surface for forming a catalytic layer. Example metal-containing precursors include those listed above. In some examples, the metal-containing precursor source 416 contains a metal-containing precursor that is in a condensed phase at standard pressure and temperature. In such examples, the metal-containing precursor source can comprise a flow-over vapor delivery system, a vaporizer delivery system, charged volume delivery system, a mole delivery device, or other suitable delivery system to volatilize the condensed phase metal-containing precursor.

The oxidizing agent source 418 can comprise any suitable oxidizing agent that can be introduced into a processing chamber to oxidize a metal-containing precursor adsorbed to a substrate. Examples include water and alcohols comprising methanol, ethanol, t-butyl alcohol, n-butyl alcohol, 2-butyl alcohol, and propanol. In some examples, an oxidizing agent can be in a condensed phase at standard pressure and temperature. In such examples, the oxidizing agent source 418 can comprise a flow-over vapor delivery system, a vaporizer delivery system, charged volume delivery system, a mole delivery device, or other suitable delivery system to volatilize the condensed phase oxidizing agent.

The silanol-based silicon oxide precursor source 419 comprises a volatile or volatilizable silanol-based silicon oxide precursor that can be converted into a SiO₂ by the catalytic layer as described above. Example silanol-based silicon oxide precursors include those listed above. In some examples, the silanol-based silicon oxide precursor source 419 contains a silanol-based silicon oxide precursor that is in a condensed phase at standard pressure and temperature. In such examples, the silanol-based silicon oxide precursor source 419 can comprise a flow-over vapor delivery system 419A, a vaporizer delivery system 419B, a charged volume delivery system 419C, a mole delivery device 419D, or other suitable delivery system to volatilize the condensed phase silanol-based silicon oxide precursor.

The optional hydrogen-containing gas source 420 can be used to form reducing environments for a plasma pre-treatment or plasma post-treatment. Example hydrogen-containing gases include molecular hydrogen (H₂) and ammonia (NH₃). Similarly, the optional oxygen-containing gas source 422 can be used to form oxidizing environments for a plasma pre-treatment or plasma post-treatment. Example oxygen-containing gases include oxygen, water, carbon dioxide (CO₂), and various nitrogen oxides, such as nitrous oxide (N₂O).

Inert gas source 424 can comprise any suitable inert gas. Examples include He, Ne, Ar, Kr, Xe, and N₂. In some examples, one or more additional inert gas sources can be included, each providing a different inert gas.

The processing tool 400 further comprises an exhaust system 425. The exhaust system 425 is configured to exhaust gases from the processing chamber 402. The exhaust system 425 can comprise any suitable hardware, including one or more low vacuum pumps and one or more high vacuum pumps.

The processing tool 400 further comprises a radiofrequency power source 426 that is electrically connected to substrate support 404. The radiofrequency power source 426 is configured to form a plasma. For example, a plasma can be used to perform a plasma pre-treatment or a plasma-post treatment. In other examples, the plasma pre-treatment and plasma post-treatment can be performed in a different processing tool.

The processing tool 400 further includes a matching network 428 for impedance matching of the radiofrequency power source 426. The radiofrequency power source 426 can be configured to provide RF energy of any suitable frequency and power. Example frequencies include 400 kHz, 13.56 MHz, 27 MHz, 60 MHz, and 90 MHz. In some examples, the radiofrequency power source 426 is configured to operate at a plurality of different frequencies and/or powers. Examples of lower frequencies include frequencies of 3 MHz and below. The lower frequency radiofrequency energy component can comprise a power of up to 6500 W. Examples of suitable high-frequency RF power includes frequencies within a range of 3 MHz to 300 MHz. The higher frequency radiofrequency energy component can comprise a power of up to 6500 W.

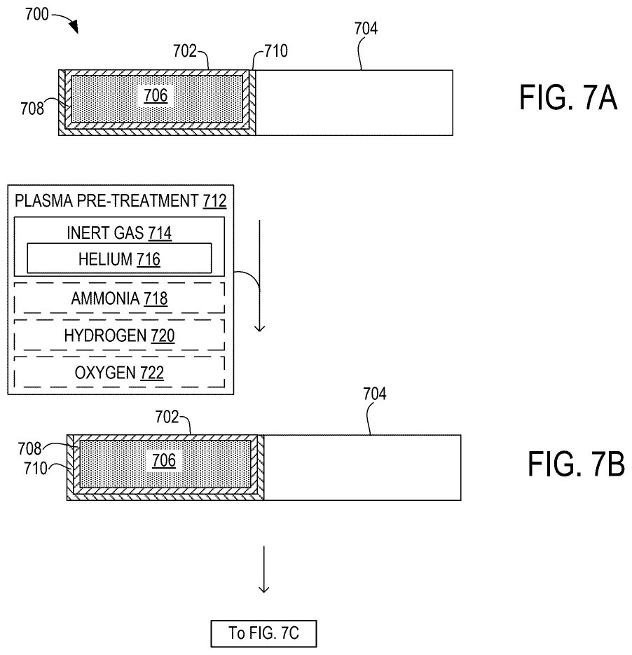

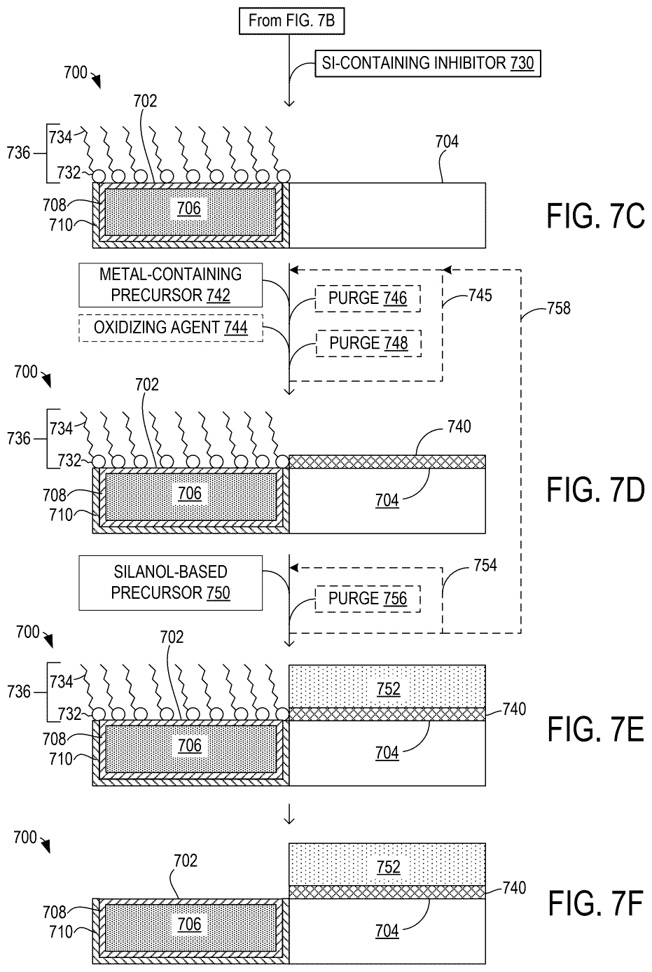

The controller 430 is operatively coupled to the substrate heater 408, the flow control hardware 412, the exhaust system 425, and the radiofrequency power source 426. The controller 430 is configured to control various functions of the processing tool 400 to perform a thin film deposition process, such as an TALD process. For example, the controller 430 is configured to operate the substrate heater 408 to heat a substrate to a desired temperature. The controller 430 also is configured to operate the flow control hardware 412 to flow a selected gas or mixture of gases at a selected rate into the processing chamber 402. The controller 430 is further configured to operate the exhaust system 425 to remove gases from processing chamber 402. The controller 430 can, for example, control the exhaust system 425 and/or the flow control hardware 412 to purge the processing chamber 402. When performing a PEALD process, a plasma pre-treatment, or a plasma post-treatment, the controller 430 is configured to operate the radiofrequency power source 426 for a selected duration to form a plasma. The controller 430 can comprise any suitable computing system. Example computing systems are described below with reference to FIG. 7.

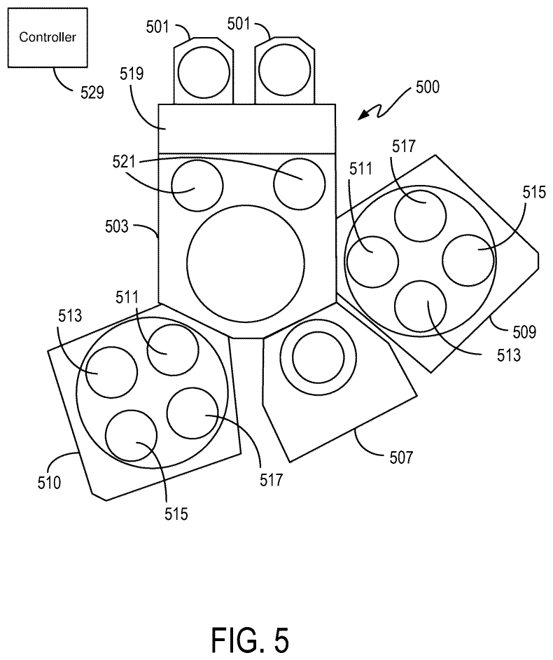

As mentioned above, in some examples, various processes described herein can be performed in different processing tools. FIG. 5 is a schematic view of a processing system 500 that comprises multiple processing tools coupled by a transfer module 503. The transfer module 503 provides a clean, pressurized environment to avoid contamination of substrates being processed as they are moved between various processing tools. Mounted on the transfer module 503 are two multi-station processing tools 509 and 510. In some examples, each processing tool 509 and 510 can be capable of performing one or more of exposing a substrate to a Si-containing inhibitor, performing pre-treatment, exposing the substrate to a metal-containing precursor, exposing the substrate to a silanol-based silicon oxide precursor, and/or performing post-treatment.

Processing tools 509 and 510 each comprises multiple processing stations 511, 513, 515, and 517 that can sequentially or non-sequentially perform any of the methods and/or processes described herein. The processing stations 511, 513, 515, and 517 in each of processing tools 509 and 510 can include a heated pedestal, and a showerhead. The processing tool 400 is an example of a station that can be implemented as processing stations 511, 513, 515, and 517.

Also mounted on the transfer module 503 can be one or more single or multi-station process modules, such as process module 507, capable of performing plasma or chemical (non-plasma) pre-cleans, or any other processes described in relation to the described methods. The process module 507 can be used, for example, to expose a substrate to a Si-containing inhibitor, to perform a plasma pre-treatment, to expose the substrate to a metal-containing precursor, to expose the substrate to a silanol-based silicon oxide precursor, and/or to perform a plasma post-treatment.

The system 500 also includes one or more substrate source modules 501, where substrates are stored before and after processing. An atmospheric robot (not shown) in the atmospheric transfer chamber 519 can first remove substrates from the source modules 501 to load locks 521. A substrate transfer device (for example, a robot arm unit) in the transfer module 503 moves the substrates from load locks 521 to and among the modules mounted on the transfer module 503.

In various examples, a controller 529 is employed to control process conditions during deposition. The controller 529 can include one or more memory devices and one or more processors. A processor can include a CPU or computer, analog and/or digital input/output connections, stepper motor controller boards, etc. Example hardware for the controller 529 is described in more detail below.

The controller 529 can control all of the activities of the deposition apparatus. The system controller 529 executes system control software, including sets of instructions for controlling the timing, mixture of processing chemicals, chamber pressure, chamber temperature, substrate temperature, radio frequency (RF) power levels for plasma pre-treatments, substrate chuck or pedestal position, and other parameters of a particular process. Other computer programs stored on memory devices associated with the controller 529 can be employed in some examples.

In some examples, the controller 529 comprises a user interface. The user interface can include a display screen, graphical software displays of the apparatus and/or process conditions, and user input devices such as pointing devices, keyboards, touch screens, microphones, etc.

The controller parameters relate to process conditions, such as, for example, process gas composition and flow rates, temperature, pressure, cooling gas pressure, substrate temperature, and chamber wall temperature. These parameters are provided to the user in the form of a recipe, and can be entered utilizing the user interface. Signals for monitoring the process can be provided by analog and/or digital input connections of the system controller 529. The signals for controlling the process are output on the analog and digital output connections of the system 500.

The system software can be designed or configured in many different ways. For example, various chamber component subroutines or control objects can be written to control operation of the chamber components necessary to carry out the deposition processes (and other processes, in some cases) in accordance with the methods and processes described herein. Examples of programs or sections of programs for this purpose include substrate positioning code, process gas control code, pressure control code, and heater control code. Example hardware for controller 529 is described below with regard to FIG. 7.

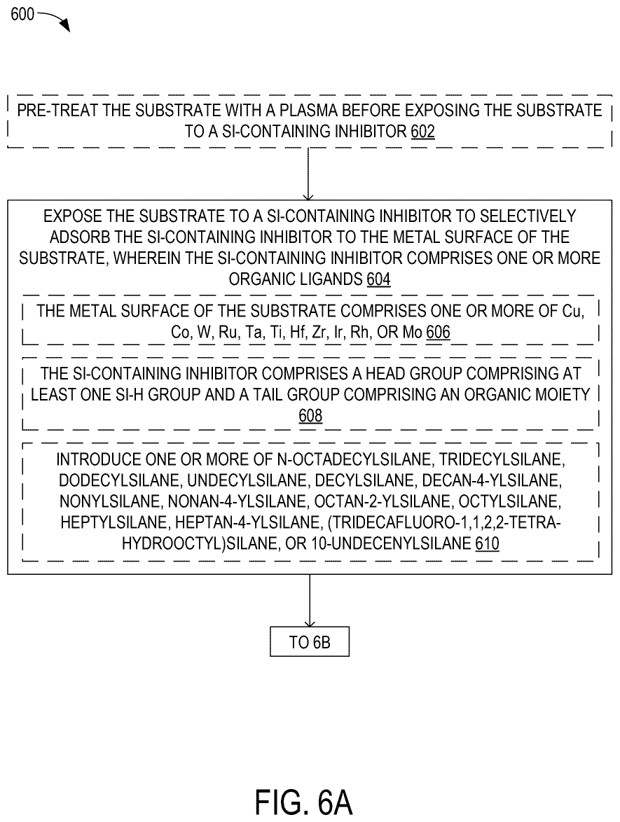

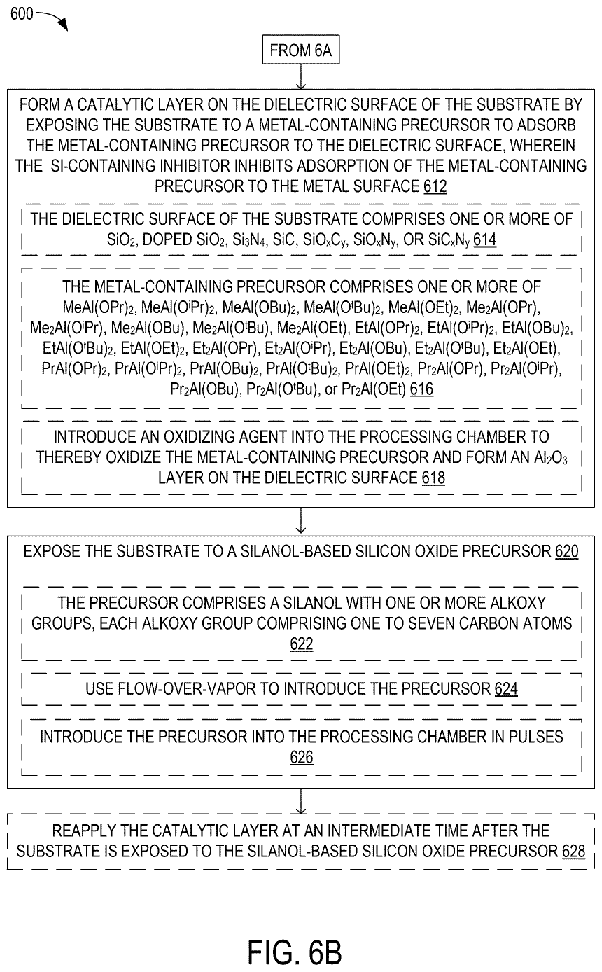

FIGS. 6A-6B show a flow diagram depicting an example method 600 for selectively depositing SiO₂ on a substrate comprising a metal surface and a dielectric surface. The following description of the method 600 is provided with reference to FIGS. 1-5 above. It will be appreciated that the method 600 also can be performed in other contexts.

In some examples, at 602, the method 600 comprises pre-treating the substrate with a plasma comprising O₂ and H₂ before exposing the substrate to a Si-containing inhibitor. For example, the substrate 100 of FIG. 1 can be pre-treated with a plasma comprising H₂, O₂, and optionally an inert carrier gas (e.g., He, Ne, Ar, Kr, Xe). The plasma can be used to clean the substrate and activate portions of the substrate (e.g., the barrier layer 105) to enable adsorption of the Si-containing inhibitor.

At 604, the method 600 comprises exposing the substrate to a Si-containing inhibitor to selectively adsorb the Si-containing inhibitor to the metal surface of the substrate. The Si-containing inhibitor comprises one or more organic ligands. In some examples, at 606, the metal surface of the substrate comprises one or more of Cu, Co, W, Ru, Ta, Ti, Hf, Zr, or Mo. It will also be appreciated that the metal surface of the substrate can include any other suitable metal, a combination of two or more metals, and/or doped forms thereof. As an illustrative example, the substrate 100 can comprise a copper line partially surrounded by a protective cap comprising Co protective cap, and a barrier layer comprising Ta and/or TaN.

As indicated at 608, the Si-containing inhibitor can comprise a head group comprising at least one Si—H group and a tail group comprising an organic moiety. For example, the Si-containing inhibitor 108 of FIG. 1 comprises a head group 112 proximate to the metal surface 102 and a tail group 114 oriented away from the metal surface 102. In some such examples, this enables self-assembly of the Si-containing inhibitor 108 into an inhibitor layer 110.

As indicated at 610, more specific examples of the Si-containing inhibitor include n-octadecylsilane, tridecylsilane, dodecylsilane, undecylsilane, decylsilane, decan-4-ylsilane, nonylsilane, nonan-4-ylsilane, octan-2-ylsilane, octylsilane, heptylsilane, heptan-4-ylsilane, (tridecafluoro-1,1,2,2-tetra-hydrooctyl) silane, or 10-undecenylsilane.

With reference now to FIG. 6B, at 612, the method 600 further comprises forming a catalytic layer on the dielectric surface of the substrate by exposing the substrate to a metal-containing precursor to adsorb the metal-containing precursor to the dielectric surface. As described above, the Si-containing inhibitor inhibits adsorption of the metal-containing precursor to the metal surface. In various examples, the dielectric surface of the substrate comprises one or more of SiO₂, doped SiO₂, Si₃N₄, SiC, SiOₓC_{y}, SiOₓN_{y}, or SiCₓN_{y}, as indicated at 614.

In some examples, as indicated at 616, the metal-containing precursor comprises an Al-containing precursor. Examples of Al-containing precursors include one or more of MeAl(OPr)₂, MeAl(OⁱPr)₂, MeAl(OBu)₂, MeAl(O^{t}Bu)₂, MeAl(OEt)₂, Me₂Al(OPr), Me₂Al(OⁱPr), Me₂Al(OBu), Me₂Al(O^{t}Bu), Me₂Al(OEt), EtAl(OPr)₂, EtAl(OⁱPr)₂, EtAl(OBu)₂, EtAl(O^{t}Bu)₂, EtAl(OEt)₂, Et₂Al(OPr), Et₂Al(OⁱPr), Et₂Al(OBu), Et₂Al(O^{t}Bu), Et₂Al(OEt), PrAl(OPr)₂, PrAl(OⁱPr)₂, PrAl(OBu)₂, PrAl(O^{t}Bu)₂, PrAl(OEt)₂, Pr₂Al(OPr), Pr₂Al(OⁱPr), Pr₂Al(OBu), Pr₂Al(O^{t}Bu), or Pr₂Al(OEt).

Forming the catalytic layer can optionally comprise, as indicated at 618, introducing an oxidizing agent into the processing chamber to thereby oxidize the Al-containing precursor and form an Al₂O₃ layer on the dielectric surface. For example, the substrate can be exposed to water and/or an alcohol to convert the Al-containing precursor to Al₂O₃. In some examples, one or more ALD cycles can be used to form the Al₂O₃ layer with any suitable depth. In some examples, the alcohol can comprise a 3-8 carbon alcohol. Some examples of suitable alcohols include isopropyl alcohol, 1-butyl alcohol, 2-butyl alcohol, or t-butyl alcohol. In some more specific examples, the alcohol reacts with the Al-containing precursor without oxidizing the metal surface. As described above, in other examples, the adsorbed Al-containing precursor can serve as a catalytic layer without converting the adsorbed Al-containing precursor to Al₂O₃.

At 620, the method 600 comprises exposing the substrate to a silanol-based silicon oxide precursor, wherein the catalytic layer catalyzes a conversion of the silanol-based silicon oxide precursor to SiO₂. As described above, the catalytic layer converts the silanol-based silicon oxide precursor to a SiO₂ polymer that grows upward from the catalytic layer. Some examples of suitable silanol-based silicon oxide precursors include a silanol with one or more alkoxy groups, as indicated at 622. Each alkoxy group can comprise one to seven carbon atoms.

As indicated at 624, in some examples, introducing the silanol-based silicon oxide precursor comprises using flow-over-vapor to introduce the silanol-based silicon oxide precursor into the processing chamber. As described above, the silanol-based silicon oxide precursor can be in a condensed phase at standard pressure and temperature. Accordingly, a flow-over vapor delivery system (e.g., the flow-over vapor delivery system 419A of FIG. 4) can be used to volatilize the condensed phase silanol-based silicon oxide precursor and introduce the silanol-based silicon oxide precursor into the processing chamber. In other examples, other delivery systems can be used. Examples include vaporizer 419B, charged volume system 419C, and mole delivery system 419C. A mole delivery system 419C comprises a combination of a charged volume and a vaporizer system.

In some examples, at 626, exposing the substrate to the silanol-based silicon oxide precursor comprises introducing the silanol-based silicon oxide precursor into the processing chamber in a plurality of pulses. As described above, cross-linking and thickening of the SiO₂ layer 126 can make it increasingly difficult for the additional molecules of the silanol-based silicon oxide precursor 124 to reach the catalytic layer 116 as the SiO₂ layer 126 grows. Providing the silanol-based silicon oxide precursor 124 in pulses 128 can help to balance diffusion, growth and cross-linking to enable controlled growth of the SiO₂ layer 126 on the catalytic layer 116.

At 628, in some examples, the method 600 optionally includes reapplying the catalytic layer at an intermediate time after the substrate is exposed to the silanol-based silicon oxide precursor. As described above, growth of the SiO₂ layer 126 of FIGS. 1A-1F slows the conversion of the silanol-based silicon oxide precursor 124 to the SiO₂ layer 126. Reapplication of the catalytic layer 116 on top of the SiO₂ layer 126 enables continued deposition of the SiO₂ layer 126 after an initial phase of growth slows or stops.

Thus, the use of the Si-containing inhibitor can allow for the deposition of metal oxide layers with reduced edge placement errors and tiger tooth errors compared to other deposition methods. Furthermore, the silanol-based silicon oxide precursor-derived SiO₂ has a lower K than Al₂O₃. This can reduce RC delay relative to integrated circuit devices comprising higher-k materials. As a result, relatively smaller integrated circuit elements can be fabricated with similar accuracy to relatively larger integrated circuit elements using a same process.

As mentioned above, a silicon-containing inhibitor comprising one or more organic moieties may not adsorb readily to a barrier layer, such as tantalum or tantalum nitride. This can result in some dielectric material depositing over the barrier layer in a subsequent deposition process. This can cause edge alignment errors. One potential method of activating a tantalum-containing barrier layer to allow adsorption of a silicon-containing inhibitor is to perform a two-step pre-treatment, an example of which is described for step 107 of FIG. 1. As a review, an ammonia plasma is applied to the substrate, followed by an oxygen/hydrogen plasma. The ammonia plasma can help to reduce nucleation delay of a dielectric material layer on a dielectric surface of the substrate by making the dielectric surface more hydrophilic. The hydrogen/oxygen plasma can hydroxylate the surface of the barrier layer.

However, the use of an ammonia plasma followed by a hydrogen/oxygen plasma can pose some difficulties. For example, an ammonia plasma process can utilize a higher substrate temperature than a hydrogen/oxygen plasma process. As such, using both processes as a two-step pre-treatment can involve using a different processing chamber for the ammonia plasma treatment than for the hydrogen/oxygen plasma treatment. Moving substrate between processing chambers for these two processes can result in relatively slow throughput. Further, the ammonia plasma and the hydrogen/oxygen plasma can potentially damage a dielectric surface. This can negatively impact dielectric properties such as time-dependent dielectric breakdown and dielectric constant.

Accordingly, examples are disclosed that relate to pre-treating a substrate comprising a metal surface, a barrier layer surface, and a dielectric surface to provide for adhesion of a silicon-containing inhibitor to the barrier layer surface and metal surface, while avoiding damage to a dielectric surface. Briefly, the disclosed examples expose a substrate to a plasma comprising an inert gas to pre-treat the substrate. The substrate comprises a metal surface, a barrier layer surface, and a dielectric surface. The inert gas can comprise helium. The method further comprises exposing the substrate to a silicon-containing inhibitor to selectively adsorb the silicon-containing inhibitor to a metal surface and a barrier layer surface of the substrate. The silicon-containing inhibitor comprises one or more organic moieties. The method further comprises exposing the substrate to a metal-containing precursor to adsorb the metal-containing precursor to a dielectric surface of the substrate. The silicon-containing inhibitor inhibits adsorption of the metal-containing precursor to the metal surface and the barrier layer surface. In this manner, a dielectric layer can then be selectively deposited over the dielectric surface of the substrate, without depositing over the metal layer or the barrier layer. By exposing the substrate to the plasma comprising the inert gas, the surface of the barrier layer can bind the silicon-containing inhibitor more strongly than without exposure to the plasma comprising the inert gas. Further, the use of helium as the inert gas can provide the additional advantage that relatively higher plasma powers can be used compared to heavier inert gases without potentially damaging a substrate surface. The following disclosed examples allow pre-treatment of a substrate to be performed in a single chamber prior to exposure of the substrate to the silicon-containing inhibitor. This can provide for higher throughput than where a substrate is pre-treated with an ammonia plasma process and a hydrogen/oxygen plasma process in different processing chambers.

FIGS. 7A-7F schematically show a cross-sectional view of a substrate 700 at various stages in a selective dielectric material deposition process. Referring first to FIG. 7A, the substrate 700 comprises a metal surface 702 and a dielectric surface 704. Metal surface 702 is a surface of a cap layer 708 formed around a metal line 706. In some examples, the metal line 706 comprises copper (Cu). In some such examples, the cap layer 708 comprises cobalt (Co). In other examples, other suitable metals can be used for the metal line 706 and/or cap layer 708. Examples include tungsten (W), ruthenium (Ru), rhodium (Rh), iridium (Ir), titanium (Ti), hafnium (Hf), zirconium (Zr), and molybdenum (Mo).

The metal surface 702 is at least partially surrounded by a barrier layer 710. In some examples, the barrier layer 710 can comprise Ta. As a more specific example, the barrier layer 710 can be formed from tantalum nitride. In other examples, other suitable materials can be used for the cap layer 708 and the barrier layer 710. Further examples of suitable materials include Rh and Ir.

The dielectric surface 704 can comprise any suitable dielectric material. Examples include SiO₂, doped SiO₂ (e.g., carbon-doped or fluorine-doped SiO₂), silicon nitride (Si₃N₄), silicon carbide (SiC), silicon oxycarbide (SiOₓC_{y}), silicon oxynitride (SiOₓN_{y}), and silicon carbon nitride (SiCₓN_{y}). While silicon carbide can be considered a semiconductor, the band gap of silicon carbide may be sufficiently high for silicon carbide to be used as a dielectric material in some applications. The substrate structures shown in FIGS. 7A-7F represent layers that are formed over other underlying layers. Such underlying layers are of arbitrary composition, and are not shown in FIGS. 7A-7F for the purpose of clarity.

Next, as illustrated in FIG. 7B, the substrate 700 is exposed to a plasma pre-treatment 712. As mentioned above, a silicon-containing inhibitor can have less affinity for Ta or TaN in barrier layer 710 than for cobalt of the cap layer 708 or Cu of the metal surface 702. As further mentioned above, while a plasma pre-treatment utilizing comprising oxygen (O₂) and hydrogen (H₂) to form hydroxyl radicals can be used to allow the silicon-containing inhibitor to adsorb to the barrier layer, such a pre-treatment also may damage dielectric surface 704. Thus, plasma pre-treatment 712 utilizes a plasma comprising an inert gas 714. Ions of the inert gas formed in the plasma impinge the surfaces of the substrate 700. In some examples, the inert gas comprises helium 716. It has been found that a plasma treatment utilizing helium can improve the adhesion of a silicon-containing inhibitor to a tantalum-containing barrier layer, such as a tantalum nitride barrier layer. Further, helium ions are relatively lightweight compared to other inert gas ions, such as argon ions. Thus, a helium plasma pre-treatment may pose less risk of damaging the dielectric surface 704 than an argon plasma. It also has been found that a single step plasma pre-treatment using helium can be used in place of a two-stage plasma pre-treatment comprising an ammonia plasma process followed by an oxygen/hydrogen plasma process.

In some examples, an inert gas plasma pre-treatment can comprise other processing gases in addition to the inert gas. For example, the inert gas plasma pre-treatment 712 can comprise a quantity of ammonia 718. As mentioned above, ammonia can help to increase a hydrophilicity of the dielectric surface 704 by removing materials such as carbon or nitrogen that can be in the dielectric surface 704. Likewise, in some examples, the inert gas plasma-pretreatment 712 can comprise hydrogen 720. Hydrogen also can increase a hydrophilicity of the dielectric source 704. Further, in some examples, oxygen 722 also can be used in the inert gas plasma pre-treatment 712. In some examples in which other gases are used besides the inert gas, the inert gas can be a majority of the partial pressure of the plasma. As an illustrative example, where helium is flowed at 500-20,000 standard cubic centimeters per minute (sccm), the hydrogen can be flowed at a rate of 500-6000 sccm, and oxygen can be flowed at 1-2000 sccm. In other examples, other suitable flow rates can be used. In some examples, the inert gas can be used alone. Further in some examples, the inert gas can be used with a very low flow of oxygen, such as 1-10 sccm of oxygen as compared to a flow of 500-20,000 1 sccm for the inert gas.

The inert gas plasma pre-treatment can be performed at various different pressures. In some examples, the inert gas plasma pre-treatment is performed at a pressure within a range of 0.1 Torr to 20 Torr. Pressures at the lower end of this range can provide for longer ion mean free paths than pressures at the higher end of this range. Longer mean free paths can provide for an ion flux distribution that is more vertical (with reference to a substrate surface plane) than shorter mean free paths. As such lower pressures in this range can be used to pre-treat surfaces at the bottom of trenches. Higher pressures in this range can be used to pre-treat more planar surfaces. Further, higher pressures in this range can be used for gas mixtures that include helium as well as heavier molecules such as ammonia. Higher pressures reduce the mean free path of ions formed in the plasma relative to lower pressures. This can help to prevent damage to the dielectric surface 704 from the heavier species in the gas mixture. In other examples, pressures outside of this range can be used. In some examples, the plasma pre-treatment can be performed for a duration within a range of one second to sixty seconds. In other examples, a duration outside of this range can be used.

The inert gas plasma pre-treatment can be performed using any suitable RF power for the plasma. In some examples, the inert gas plasma pre-treatment is performed using a capacitively coupled plasma having a power of 50 to 600 W (watts). Such low powers may help to prevent damage to the dielectric surface 704. In other examples, the inert gas plasma pre-treatment can be performed using an inductively coupled plasma having a power of 2000-4000 W (2-4 kilowatts). Any suitable frequency of RF energy can be used for the plasma. Examples frequencies are described below for FIG. 4. Further, the substrate can be held at any suitable temperature for the inert gas plasma pre-treatment. Examples include temperatures within a range of 50-400 degrees Celsius.

Referring next to FIG. 7C, the substrate is exposed to a silicon-containing inhibitor 730. The silicon-containing inhibitor 730 comprises a head group 732 and a tail group 734. The head group 732 is located proximate to the metal surface 702. In other examples, at least some molecules of the silicon-containing inhibitor 730 are oriented in a different direction. Adsorbed silicon-containing inhibitor 730 forms an inhibitor layer 736 For example, the inhibitor layer 736 can include an ordered layer with precise head group orientation to the metal surface 702 and/or a disordered layer with some head groups oriented in different directions.

In some examples, the inhibitor layer 736 is a monolayer. The monolayer comprises a single layer of the silicon-containing inhibitor molecules. In other examples, the inhibitor layer 736 is a multilayer. The multilayer includes more than one layer of the silicon-containing inhibitor molecules. Within the multilayer, each layer can be oriented in any suitable manner. In some such examples, the multilayer can comprise a first layer in which head groups 732 are primarily oriented towards the metal surface 702. A second layer disposed above the second layer can have its tail groups 734 oriented towards the tail groups 734 of the first layer. Any suitable configuration of layers and silicon-containing inhibitors can be used. This can result in faster or more stable self-assembly of the multilayer relative to a single-layer structure.

The silicon-containing inhibitor 730 comprises at least one silicon atom and one or more organic moieties. In some examples, the silicon-containing inhibitor 730 includes at least one Si—H bond or group. In other examples, the silicon-containing inhibitor 730 includes at least three Si—H bonds and an organic moiety (e.g., RSiH₃, in which R is the organic moiety).

In some examples, the head group 732 of the silicon-containing inhibitor 730 comprises a silicon atom and the tail group 734 comprises an organic moiety. In other examples, the head group 732 comprises —SiH or —SiX¹ or —SiHX¹X², in which each of X¹ and X² independently comprises hydrogen (H), a halogen, an aliphatic group, a substituted aliphatic group, a cycloaliphatic group, a substituted cycloaliphatic group, an aromatic group, or a substituted aromatic group. In some more specific examples, each of X¹ and X² is, independently, selected from H, fluorine (F), chlorine (Cl), bromine (Br), or iodine (I). In other more specific examples, each of X¹ and X² is, independently, selected from H, a halogen, a 6-carbon alkyl group, or a substituted 6-carbon alkyl group. In further examples, the head group can have any other suitable composition.

In some examples, the organic moiety of the tail group comprises an aliphatic group, a substituted aliphatic group, a heteroaliphatic group, a substituted heteroaliphatic group, a cycloaliphatic group, a substituted cycloaliphatic group, a cycloheteroaliphatic group, a substituted cycloheteroaliphatic group, an aromatic group, or a substituted aromatic group. In other examples, the organic moiety comprises an alkyl group, a substituted alkyl group, an alkenyl group, a substituted alkenyl group, an alkynyl group, a substituted alkynyl group, a heteroalkyl group, a substituted heteroalkyl group, a heteroalkenyl group, a substituted heteroalkenyl group, a heteroalkynyl group, a substituted heteroalkynyl group, a cycloalkyl group, a substituted cycloalkyl group, a cycloheteroalkyl group, a substituted cycloheteroalkyl group, an aryl group, a substituted aryl group, a heterocyclyl group, or a substituted heterocyclyl group. In some more specific examples, the organic moiety comprises a branched-chain hydrocarbon. In other examples, the organic moiety comprises an alkyl group having one or more halogen substitutions (e.g., one or more fluorine substitutions).

In further examples, the organic moiety of the tail group comprises —X-L-Z. X comprises a covalent bond, an alkylene group, a substituted alkylene group, an alkenylene group, a substituted alkenylene group, an alkynylene group, a substituted alkynylene group, an alkyleneoxy group, a substituted alkyleneoxy group, a heteroalkylene group, a substituted heteroalkylene group, a heteroalkenylene group, a substituted heteroalkenylene group, a heteroalkynylene group, a substituted heteroalkynylene group, an arylene group, a substituted arylene group, an aryleneoxy group, a substituted aryleneoxy group, a heterocyclyl diyl group, or a substituted heterocyclyl diyl group. L comprises a covalent bond, —CR¹R²—, —CR¹—CR²—, —NR¹—, —C(O)—, —C(O)NR¹—, —NR¹C(O)—, —C(O)O—, —OC(O)—, —S—, or —O—. Each of R¹ and R² comprises, independently, H, an alkyl group, or a substituted alkyl group. Z comprises H, an alkyl group, a substituted alkyl group, an alkenyl group, a substituted alkenyl group, an alkynyl group, a substituted alkynyl group, a heteroalkyl group, a substituted heteroalkyl group, a heteroalkenyl group, a substituted heteroalkenyl group, a heteroalkynyl group, a substituted heteroalkynyl group, an aryl group, a substituted aryl group, a heterocyclyl group, or a substituted heterocyclyl group. In other examples, X comprises an alkylene group or a substituted alkylene group. L comprises a covalent bond, —CR¹R²—, —CR¹—CR²—, —NR¹—, —C(O)—, —C(O)NR¹—, —NR¹C(O)—, —C(O)O—, —OC(O)—, —S—, or —O—. Each of R¹ and R² comprises, independently, H, a 6-carbon alkyl group, or a substituted 6-carbon alkyl group. Z comprises H, an alkyl group, or a substituted alkyl group.

In some examples, the organic moiety of the tail group comprises 6 to 26 carbon atoms (e.g., 6 to 24, 6 to 20, 6 to 18, 8 to 26, 8 to 24, 8 to 20, 8 to 18, 10 to 26, 10 to 24, 10 to 20, or 10 to 18 carbon atoms). The carbon atoms can form a linear chain, a branched chain, or a cyclic group. In some more specific examples, the organic moiety comprises a 26-carbon alkyl group, a substituted 26-carbon alkyl group, a 26-carbon alkenyl group, a substituted 26-carbon alkenyl group, a 26-carbon alkynyl group, a substituted 26-carbon alkynyl group, a 26-carbon heteroalkyl group, a substituted 26-carbon heteroalkyl group, a 26-carbon heteroalkenyl group, a substituted 26-carbon heteroalkenyl group, a 26-carbon heteroalkynyl group, a substituted 26-carbon heteroalkynyl group, a 26-carbon cycloalkyl group, a substituted 26-carbon cycloalkyl group, a 26-carbon cycloheteroalkyl group, a substituted 26-carbon cycloheteroalkyl group, a 26-carbon aryl group, a substituted 26-carbon aryl group, a 26-carbon heterocyclyl group, or a substituted 26-carbon heterocyclyl group.

In some more specific examples, the silicon-containing inhibitor 130 can comprise n-octadecylsilane (C₁₈H₄₀Si), tridecylsilane (C₁₃H₃₀Si), dodecylsilane (C₁₂H₂₈Si), undecylsilane (C₁₁H₂₆Si), decylsilane (C₁₀H₂₄Si), decan-4-ylsilane (C₁₀H₂₄Si), nonylsilane (C₉H₂₂Si), nonan-4-ylsilane (C₉H₂₂Si), octan-2-ylsilane (C₈H₂₀Si), octylsilane (C₈H₂₀Si), heptylsilane (C₇H₁₈Si), heptan-4-ylsilane (C₇H₁₈Si), (tridecafluoro-1,1,2,2-tetra-hydrooctyl) silane (C₈H₇F₁₃Si), or 10-undecenylsilane (C₁₁H₂₄Si).

Properties of the inhibitor layer 736 can be characterized by its mass change, which can indicate the number of intact or cleaved inhibitor molecules; its water contact angle (WCA), which can indicate the density or packing of the layer(s); and/or its C—H bending or stretching modes using Fourier-transform infrared spectroscopy (FTIR), can indicate the density or packing of the layer(s). In some examples, the inhibitor layer is characterized by a WCA of more than about 100° or from about 100° to 120°.

The silicon-containing inhibitor 730 can be introduced to the metal surface 702 under any suitable process conditions. In some examples, the silicon-containing inhibitor is provided by vapor soaking. In some such examples, the silicon-containing inhibitor can be provided in a processing chamber with a dose time of about 5 seconds to 600 seconds. The silicon-containing inhibitor can be provided at a substrate temperature within a range of about 50° C. to 400° C. in some examples. In some more specific examples, the silicon-containing inhibitor can be provided at a substrate temperature within a range of 50° C. to 100° C. Further, in some examples, the silicon-containing inhibitor can be provided at a pressure of about 5 Torr to 10 Torr. In some examples, the silicon-containing inhibitor is provided with an inert carrier gas (e.g., nitrogen (N₂), helium (He), neon (Ne), argon (Ar), krypton (Kr), or xenon (Xe)). In other examples, an inert gas is omitted. Delivery of the silicon-containing inhibitor 730 can be continuous or in pulses.

Process conditions can be adjusted based upon the composition and chemical characteristics of the silicon-containing inhibitor and the metal oxide to be deposited. For example, adsorption of the silicon-containing inhibitor can be characterized by mass change and/or a WCA at various pedestal temperatures (e.g., from 120° C. to 300° C.) or pressures (e.g., from 5 to 10 Torr). In some examples, a WCA of about 100° or more can be obtained. Other examples can include chemical characterization of the inhibitor layer 736, such as by FTIR, transmission electron microscopy (TEM), cross-sectional transmission electron microscopy (XTEM), and/or energy-dispersive X-ray spectroscopy (EDS). Additional details regarding processing conditions and tools are described in more detail below with reference to FIGS. 2-6B.

Next, as shown in FIG. 7D, a metal oxide catalytic layer 740 is formed on the dielectric surface 704. The formation of the catalytic layer 740 comprises exposing the substrate 700 to a metal-containing precursor 742. The metal-containing precursor 742 is introduced into a processing chamber in which the substrate 700 is located. The metal-containing precursor 742 adsorbs to the dielectric surface 704. The silicon-containing inhibitor 730 inhibits the metal-containing precursor 742 from adsorbing to the metal surface 702.

As described below, the metal in the metal-containing precursor 742 acts as a catalyst in the formation of a SiO₂ layer. In some examples, the adsorbed metal-containing precursor 742 is used as a catalyst, without further processing. In other examples, the metal-containing precursor 742 is further processed to convert the metal-containing precursor 742 into a metal oxide layer as the catalytic layer 740.

For example, an aluminum (Al)-containing precursor can be converted to an Al₂O₃ film. In such examples, a plurality of Al₂O₃ layers can be formed using atomic layer deposition, as described below. Examples of suitable Al-containing precursors can include methyl aluminum propoxide (MeAl(OPr)₂), methyl aluminum isopropoxide (MeAl(OⁱPr)₂), methyl aluminum butoxide (MeAl(OBu)₂), methyl aluminum t-butoxide (MeAl(O^{t}Bu)₂), methyl aluminum ethoxide (MeAl(OEt)₂), dimethyl aluminum propoxide (Me₂Al(OPr)), dimethyl aluminum isopropoxide (Me₂Al(OⁱPr)), dimethyl aluminum butoxide (Me₂Al(OBu)), dimethyl aluminum t-butoxide (Me₂Al(O^{t}Bu)), dimethyl aluminum ethoxide (Me₂Al(OEt)), ethyl aluminum propoxide (EtAl(OPr)₂), ethyl aluminum isopropoxide (EtAl(OⁱPr)₂), ethyl aluminum butoxide (EtAl(OBu)₂), ethyl aluminum t-butoxide (EtAl(O^{t}Bu)₂), ethyl aluminum ethoxide (EtAl(OEt)₂), diethyl aluminum propoxide (Et₂Al(OPr)), diethyl aluminum isopropoxide (Et₂Al(OⁱPr)), diethyl aluminum butoxide (Et₂Al(OBu)), diethyl aluminum t-butoxide (Et₂Al(O^{t}Bu)), diethyl aluminum ethoxide (Et₂Al(OEt)), propyl aluminum propoxide (PrAl(OPr)₂), propyl aluminum isopropoxide (PrAl(OⁱPr)₂), propyl aluminum butoxide (PrAl(OBu)₂), propyl aluminum t-butoxide (PrAl(O^{t}Bu)₂), propyl aluminum ethoxide (PrAl(OEt)₂), dipropyl aluminum propoxide (Pr₂Al(OPr)), dipropyl aluminum isopropoxide (Pr₂Al(OⁱPr)), dipropyl aluminum butoxide (Pr₂Al(OBu)), dipropyl aluminum t-butoxide (Pr₂Al(O^{t}Bu)), and dipropyl aluminum ethoxide (Pr₂Al(OEt)). It will be appreciated that the metal-containing precursor 742 can include any other suitable ligand(s) than the ligands of the example precursors listed above. Examples of suitable ligands include hydrocarbons, alkoxides, and/or substituted alkyl ligands. In yet other examples, the metal-containing precursor comprises any other suitable metal, such as hafnium. In other instances, metalloids (such as boron) can serve as the metal-containing precursor to form the catalytic layer 740.

The use of relatively large, bulky ligands in the metal-containing precursor 742 (e.g., larger than the methyl ligands of trimethyl aluminum (TMA)) results in steric hindrance at the inhibitor layer 736. As a result, the metal-containing precursor 742 is blocked from the metal surface 702. The use of smaller metal-containing precursors (e.g., TMA) can result in less-selective deposition as these smaller metal-containing precursors encounter less steric hindrance from the inhibitor layer. Furthermore, in some examples, the metal-containing precursor 742 has a dipole moment. As such, the metal-containing precursor 742 can be repelled by hydrophobic tail groups 734 of the silicon-containing inhibitor 730. However, the steric effects and/or polarity of the metal-containing precursor 742 do not prevent (i) adsorption of the metal-containing precursor 742 at the dielectric surface 704, and/or (ii) oxidation of the metal-containing precursor 742 as described in more detail below.

As mentioned above, in some examples, the adsorbed metal-containing precursor 742 is used as a catalytic layer 740 without further processing. In other examples, the metal-containing precursor is oxidized (e.g., Al is converted to Al₂O₃). The metal oxide then is used as catalytic layer 740. In such examples, forming the catalytic layer 740 further comprises introducing an oxidizing agent 744 into the processing chamber to thereby oxidize the metal-containing precursor 742 and form a metal oxide layer on the dielectric surface 704. The processing chamber is optionally purged at 746 before the oxidizing agent 744 is introduced. The chamber is optionally purged again at 748 after the oxidizing agent 744 is introduced into the processing chamber. In some examples, the adsorption/purge/oxidation/purge sequence can be repeated, as indicated at 745, to grow the metal oxide film layer by layer using atomic layer deposition (ALD).

In some examples, the oxidizing agent 744 comprises one or more of water or an alcohol. Some examples of suitable alcohols can include isopropyl alcohol, 1-butyl alcohol, 2-butyl alcohol, or t-butyl alcohol. The alcohol reacts with the Al-containing precursor 742 despite steric hindrance from the alcohol and/or the Al-containing precursor 742. This is facilitated by the polarity of both the alcohol and the Al-containing precursor.

Next, the substrate 700 is exposed to a silanol-based silicon oxide precursor 750. The catalytic layer 740 catalyzes a conversion of the silanol-based silicon oxide precursor 750 to SiO₂ layer 752. The silanol-based silicon oxide precursor 750 binds to a metal-containing site in the catalytic layer 740. Without wishing to be bound by theory, an additional silanol-based silicon oxide precursor molecule may also bind to the same metal-containing site. Binding of the additional silanol-based silicon oxide precursor molecule may displace a previously bound silanol-based silicon oxide precursor from the metal-containing site, which may then substitute itself for one of the alkoxy moieties on the additional silanol-based silicon oxide precursor. Cross-linking of polymerized silanol-based silicon oxide precursor chains yields SiO₂. In this manner, the metal-containing site catalyzes conversion of the silanol-based silicon oxide precursor 750 to SiO₂ from the bottom-up.

In some examples, each alkoxy group of the silanol-based silicon oxide precursor comprises one to seven carbon atoms. It will be appreciated that in examples where the silanol-based silicon oxide precursor comprises two or more alkoxy substituents, such substituents can all be identical, or some substituents can be different from one another. In other examples, larger alkoxy groups can be used. The alkoxy groups can comprise linear alkyl moieties groups, branched alkyl moieties, and/or cyclic alkyl moieties. Further, the alkoxy groups can comprise alkenyl and/or alkynyl groups in some examples. The alkoxy groups can be unsubstituted or substituted in various examples.

In some more specific examples, the silanol-based silicon oxide precursor 750 comprises one or more of mono(tert-pentoxy)silanol, bis(tert-pentoxy)silanol, tris(tert-pentoxy)silanol, mono(tert-butoxy)silanol, bis(tert-butoxy)silanol, tris(tert-butoxy)silanol, mono(isopropoxy)silanol, bis(isopropoxy)silanol, or tris(isopropoxy)silanol. It will also be appreciated that the silanol-based silicon oxide precursor 750 can include any other suitable substituents than the substituents of the example precursors listed above. Other example substituents include aromatic and antiaromatic groups.

In some examples, exposing the substrate 700 to the silanol-based silicon oxide precursor 750 comprises introducing the silanol-based silicon oxide precursor 750 into the processing chamber in one or more pulses 754. In each pulse 754, the silanol-based silicon oxide precursor 750 is introduced into the processing chamber. The processing chamber is then purged 756 before introducing another pulse 754 of the silanol-based silicon oxide precursor 750. As SiO₂ layer 752 grows, additional molecules of the silanol-based silicon oxide precursor 750 diffuse through the SiO₂ layer 752 to reach the catalytic layer 740. Cross-linking and thickening of the SiO₂ layer 752 can make it increasingly difficult for the additional molecules of the silanol-based silicon oxide precursor 750 to reach the catalytic layer 740. Providing the silanol-based silicon oxide precursor 750 in the one or more pulses 754 can help to balance diffusion, growth and cross-linking to enable controlled growth of the SiO₂ layer 752 on the catalytic layer 740.

Example treatment conditions include a treatment time in a range of 5 seconds to 1 hour, a substrate temperature of about 200° C. to 400° C., and/or a pressure of about 3 to 18 torr. Such treatment conditions can balance diffusion, growth and cross-linking of the SiO₂ layer 752 to achieve controlled growth of the SiO₂ layer 752. In other examples, other suitable conditions than these can be used to form the SiO₂ layer 752.

While FIGS. 7C-7F illustrate growing a silicon oxide film using a metal oxide catalyst after performing an inert gas plasma pre-treatment and silicon-containing inhibitor exposure, in other examples other suitable dielectric films can be grown. Examples include aluminum oxide films, silicon nitride films, silicon oxynitride films, silicon oxycarbide films, and silicon oxycarbonitride films. Such films can be deposited using ALD, for example. In some such examples, a silicon-containing inhibitor can be redeposited at an intermediate time during a dielectric film deposition process.

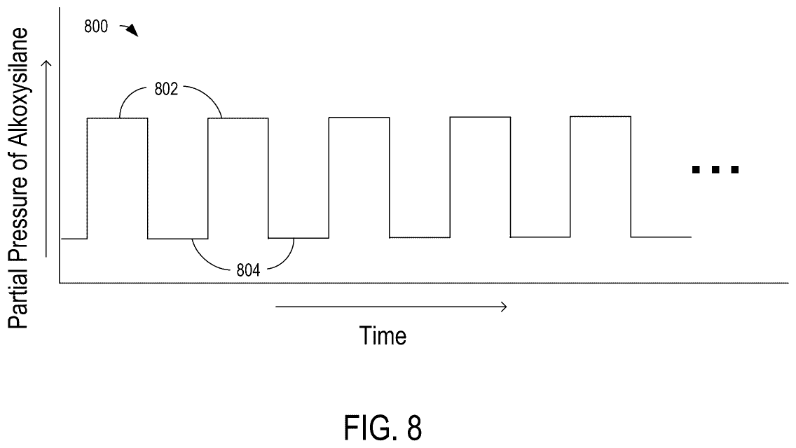

FIG. 8 schematically shows an example timing diagram 800 illustrating exposure of the substrate 700 to a silanol-based silicon oxide precursor 750. The silanol-based silicon oxide precursor is introduced into the processing chamber in a series of pulses 802 in which the silanol-based silicon oxide precursor has a first, higher partial pressure. Pulses 802 are examples of pulses 754. After performing a pulse of the alkoxy silane, the partial pressure is decreased in a purging step 704. The purging steps 704 allow silanol-based silicon oxide precursor from prior pulses to diffuse through SiO₂ layer 752 that has already grown to reach the catalyst layer 740. The pulses 802 can have any suitable duration and flow. Example durations for each pulse 802 include times in a range of 0.2 seconds-600 seconds. Example durations for each purge 804 include times in a range of 0.1 seconds to 60 seconds. In other examples, durations outside of these ranges can be used. While the silanol-based silicon oxide precursor partial pressure is shown as a square wave in the schematic depiction of claim 2, the partial pressure increase and partial pressure decrease of each pulse can have a sloped and/or curved shape in practice.

Returning to FIGS. 7C-7F, as indicated at 758, in some examples, the catalytic layer 740 is reapplied at an intermediate time after the substrate 700 is exposed to the silanol-based silicon oxide precursor 750. As described above, as the thickness of the SiO₂ layer 752 increases, a distance between an incoming silanol-based silicon oxide precursor 750 and the catalytic layer 740 increases. This slows the conversion of the silanol-based silicon oxide precursor 750 to the SiO₂ layer 752 due to the SiO₂ blocking diffusion of the silanol-based silicon oxide precursor to the catalyst layer 740. In some examples, the SiO₂ layer 752 can form a layer up to about 750 angstroms thick before another catalyst layer is deposited on the SiO₂ layer 752. Reapplication of the catalytic layer 740 on top of the SiO₂ layer 752 enables additional growth of layer of the SiO₂ layer 752.

Referring next to FIG. 7F, the substrate 700 is post-treated to remove the inhibitor layer 736 from the metal surface 702 after the catalytic layer 740 and the silicon oxide layer 752 are deposited on the dielectric surface 704. Such post-treatment can include a plasma treatment, a wet etch treatment, a dry etch treatment, or combinations of two or more thereof. As more specific examples, a post-treatment can include a plasma treatment using hydrogen (H₂) gas or ammonia (NH₃) gas, optionally with one or more inert carrier gases (e.g., He, Ne, Ar, Kr, Xe). Such post-treatment can additionally or alternatively include using a plasma treatment (e.g., a H₂/He plasma) to remove carbon from the SiO₂ layer 752. The plasma can be an inductively coupled plasma or a capacitively coupled plasma. In some examples, post-treatment conditions include a treatment time in a range of 5-35 seconds and/or a substrate temperature of about 200° C. to 400° C. In other examples, other suitable conditions than these can be used.

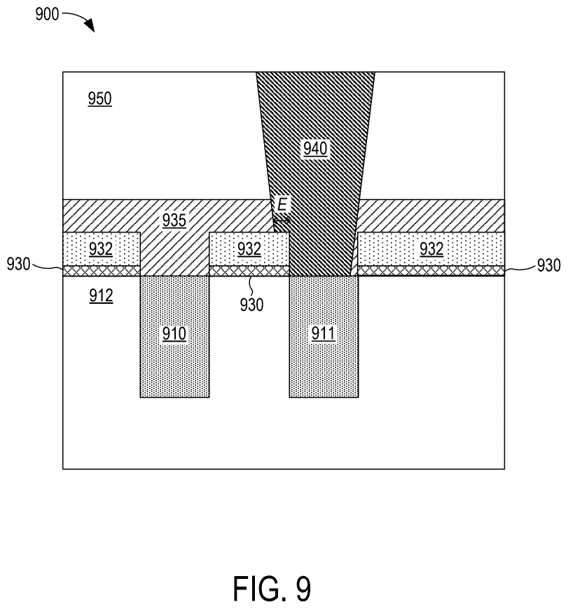

FIG. 9 schematically shows an example stack 900 of film layers formed by the processes described herein. As illustrated in FIG. 9, the stack 900 includes a dielectric layer 912 comprising metal lines 910, 911. Details of metal lines 910, 911, such as cap layer 708 and barrier layer 710 of FIGS. 7A-7F, are omitted from FIG. 9 for simplicity. With the processes herein, the metal lines 910, 911 can serve as a region upon which an inhibitor layer can be deposited. Further, the dielectric material 912 can serve as a region upon which a catalytic layer 930 can be deposited. A SiO₂ layer 932 is deposited on at least a portion of the surface of the catalytic layer 930. Further processing steps form a metal via 940 that is electrically connected to metal line 911. The further processing steps also form a cap layer 935 and an additional dielectric layer 950.

The distance between an intended and actual position on the edge of the metal via 940 can be characterized by an edge placement error E, as indicated in FIG. 9. As described above, the methods and processes described herein can contain the edge placement error E within a tolerance that prevents the metal via 940 from being placed too close to other metal lines, such as metal line 910. This can help to avoid unwanted capacitance, short-circuiting, and possibly other issues.

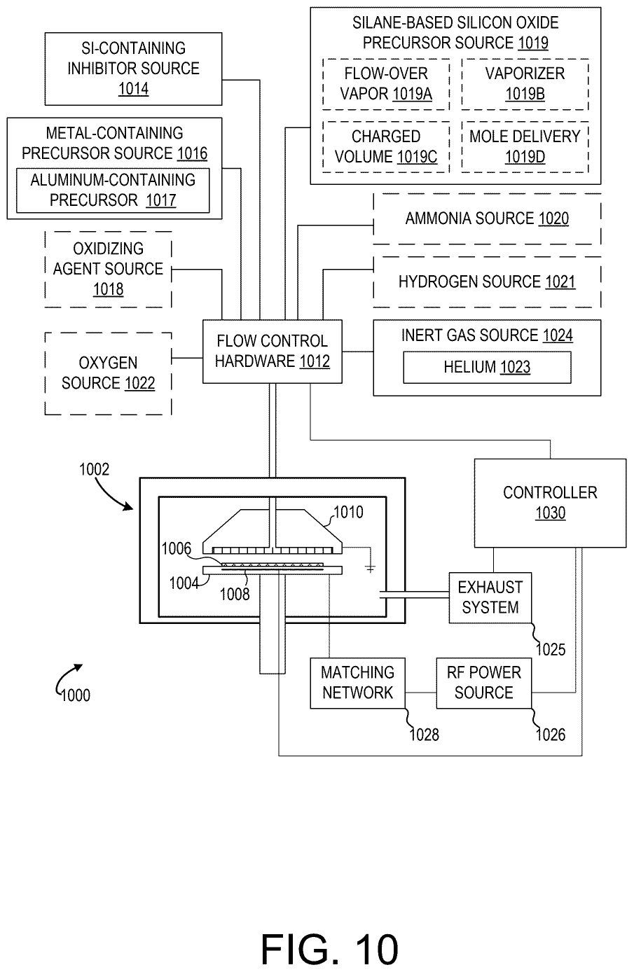

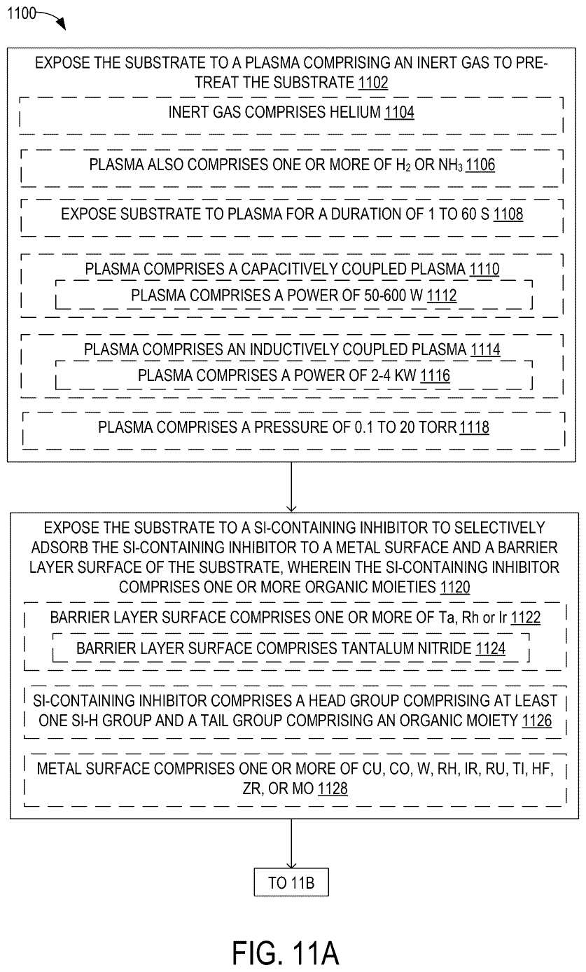

FIG. 10 shows an example of a processing tool 1000 that can be used to perform a plasma pretreatment on a substrate, selectively adsorb a silicon-containing inhibitor to the substrate, and/or deposit a dielectric film on the substrate according to the process illustrated in FIGS. 7A-7F. In other examples, one or more of these processes can be performed using a different tool.

The processing tool 1000 comprises a processing chamber 1002 and a substrate support 1004 within the processing chamber. The substrate support 1004 is configured to support a substrate 1006 disposed within the processing chamber 1002. The substrate support 1004 can comprise a pedestal, an electrostatic chuck pedestal, or any other suitable structure. The substrate support 1004 comprises a substrate heater 1008.

The processing tool 1000 further comprises a showerhead 1010. In other examples, a processing tool can comprise a nozzle or other apparatus for introducing gas into processing chamber 1002, as opposed to or in addition to a showerhead. The processing tool 1000 further comprises flow control hardware 1012. The flow control hardware 1012 connects processing gas source(s) to the processing chamber. In the depicted example, the flow control hardware 1012 connects a silicon-containing inhibitor source 1014, a metal-containing precursor source 1016, an optional oxidizing agent source 1018, an optional silanol-based silicon oxide precursor source 1019, an optional ammonia source 1020, an optional hydrogen source 1021, an optional oxygen source 1022, and an inert gas source 1024 to the processing chamber. The flow control hardware 1012 can include any suitable components. Examples include mass flow controllers, valves, and conduits.

The silicon-containing inhibitor source 1014 comprises any suitable silicon-containing inhibitor for selectively adsorbing to a metal surface. Examples include the silicon-containing inhibitors listed above. In some examples, the silicon-containing inhibitor source contains a silicon-containing inhibitor that is in a condensed phase at standard pressure and temperature. In such examples, the silicon-containing inhibitor source 1014 can comprise a flow-over-vapor delivery system, a vaporizer delivery system, charged volume delivery system, a mole delivery device, or other suitable delivery system to volatilize the condensed phase silicon-containing inhibitor.

The metal-containing precursor source 1016 comprises a volatile or volatilizable metal-containing precursor that adsorbs to a substrate surface for forming a catalytic layer. Example metal-containing precursors include those listed above. In some examples, the metal-containing precursor source 1016 contains a metal-containing precursor that is in a condensed phase at standard pressure and temperature. In such examples, the metal-containing precursor source can comprise a flow-over vapor delivery system, a vaporizer delivery system, charged volume delivery system, a mole delivery device, or other suitable delivery system to volatilize the condensed phase metal-containing precursor. In some examples, the metal-containing precursor source comprises an aluminum-containing precursor 1017. In other examples, the metal-containing precursor source can comprise precursors with metals other than aluminum.

The optional oxidizing agent source 1018 can comprise any suitable oxidizing agent that can be introduced into a processing chamber to oxidize a metal-containing precursor adsorbed to a substrate. Examples include water and alcohols comprising methanol, ethanol, t-butyl alcohol, n-butyl alcohol, 2-butyl alcohol, and propanol. In some examples, an oxidizing agent can be in a condensed phase at standard pressure and temperature. In such examples, the oxidizing agent source 1018 can comprise a flow-over vapor delivery system, a vaporizer delivery system, charged volume delivery system, a mole delivery device, or other suitable delivery system to volatilize the condensed phase oxidizing agent.

The optional silanol-based silicon oxide precursor source 1019 comprises a volatile or volatilizable silanol-based silicon oxide precursor that can be converted into a SiO₂ by the catalytic layer as described above. Example silanol-based silicon oxide precursors include those listed above. In some examples, the silanol-based silicon oxide precursor source 1019 contains a silanol-based silicon oxide precursor that is in a condensed phase at standard pressure and temperature. In such examples, the silanol-based silicon oxide precursor source 1019 can comprise a flow-over vapor delivery system 1019A, a vaporizer delivery system 1019B, a charged volume delivery system 1019C, a mole delivery device 1019D, or other suitable delivery system to volatilize the condensed phase silanol-based silicon oxide precursor.

Inert gas source 1024 can comprise any suitable inert gas. Examples include helium, neon, argon, krypton, and xenon. In some applications, nitrogen gas can be used as an inert gas. In some examples, one or more additional inert gas sources can be included, each providing a different inert gas. As described above, helium 1023 can be particularly well-suited for use in an inert gas plasma pre-treatment due at least to the low atomic mass of helium compared to other inert gases.

The processing tool 1000 further comprises an exhaust system 1025. The exhaust system 1025 is configured to exhaust gases from the processing chamber 1002. The exhaust system 1025 can comprise any suitable hardware, including one or more low vacuum pumps and one or more high vacuum pumps.

The processing tool 1000 further comprises a radiofrequency power source 1026 that is electrically connected to substrate support 1004. The radiofrequency power source 1026 is configured to form a plasma. For example, a plasma can be used to perform a plasma pre-treatment or a plasma-post treatment. In other examples, the plasma pre-treatment and plasma post-treatment can be performed in a different processing tool.

The processing tool 1000 further includes a matching network 1028 for impedance matching of the radiofrequency power source 1026. The radiofrequency power source 1026 can be configured to provide RF energy of any suitable frequency and power. Example frequencies include 400 kHz, 13.56 MHz, 27 MHz, 60 MHz, and 90 MHz. In some examples, the radiofrequency power source 1026 is configured to operate at a plurality of different frequencies and/or powers. Examples of lower frequencies include frequencies of 3 MHz and below. The lower frequency radiofrequency energy component can comprise a power of up to 6500 W. Examples of suitable high-frequency radiofrequency power includes frequencies within a range of 3 MHz to 300 MHz. The higher frequency radiofrequency energy component can comprise a power of up to 6500 W. In other examples, a processing tool can provide for other radiofrequency powers and/or frequencies.

The controller 1030 is operatively coupled to the substrate heater 1008, the flow control hardware 1012, the exhaust system 1025, and the radiofrequency power source 1026. The controller 1030 is configured to control various functions of the processing tool 1000 to perform a thin film deposition process, such as an TALD process. For example, the controller 1030 is configured to operate the substrate heater 1008 to heat a substrate to a desired temperature. The controller 1030 also is configured to operate the flow control hardware 1012 to flow a selected gas or mixture of gases at a selected rate into the processing chamber 1002. The controller 1030 is further configured to operate the exhaust system 1025 to remove gases from processing chamber 1002. The controller 1030 can, for example, control the exhaust system 1025 and/or the flow control hardware 1012 to purge the processing chamber 1002. When performing a PEALD process, a plasma pre-treatment, or a plasma post-treatment, the controller 1030 is configured to operate the radiofrequency power source 1026 for a selected duration to form a plasma. The controller 1030 can comprise any suitable computing system. Example computing systems are described below with reference to FIG. 7.

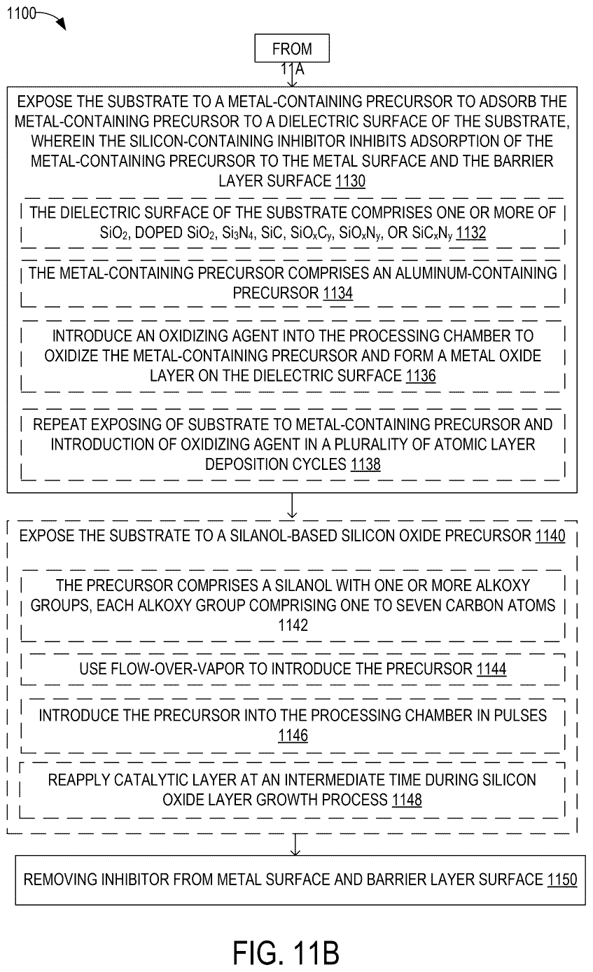

FIGS. 11A-11B show a flow diagram depicting an example method 1100 for processing a substrate according to the present disclosure. The following description of the method 1100 is provided with reference to FIGS. 7A-10 above. It will be appreciated that the method 1100 also can be performed in other contexts.

At 1102, the method 1100 comprises exposing the substrate to a plasma comprising an inert gas to pre-treat the substrate. As described above, the inert gas plasma pre-treatment can help improve an adhesion of a silicon-containing inhibitor to a barrier layer surface compared to not performing the inert gas plasma pre-treatment. The inert gas plasma pre-treatment also can help to increase a hydrophilicity of a dielectric surface on a substrate compared to not performing the inert gas plasma pre-treatment. In some examples, the inert gas can comprise helium 1104. The small atomic mass of helium compared to other inert gases can allow relatively higher power plasmas to be used than the use of other inert gases, such as argon.

In some examples, the inert gas plasma pre-treatment can be performed using only the inert gas. In other examples, one or more other gases can be used with the inert gas plasma pre-treatment. Examples include hydrogen and/or ammonia 1106. Further, in some examples, a quantity of oxygen can be used in the plasma. In such examples, as described above, an oxygen gas flow rate can be substantially below an inert gas flow rate. Example gas flow rates are described above. The substrate can be exposed to the inert gas plasma pre-treatment for any suitable duration of time. In some examples, the substrate is exposed to the inert gas plasma pre-treatment for a duration of 1 to 60 seconds, as indicated at 1108. In other examples, a duration outside of this range can be used.

In some examples, an inert gas plasma pre-treatment can be performed using a capacitively coupled plasma 1110. In some such examples, a plasma power within a range of 50-600 W can be used, as indicated at 1112. In other examples, an inert gas plasma pre-treatment can be performed using an inductively coupled plasma 1114. In some such examples, a plasma power of 2 to 4 kW can be used, as indicated at 1116. Example radiofrequency power frequencies are given above. As described above, an inert gas plasma pre-treatment can be performed at various pressures. In some examples, the inert gas plasma pre-treatment can be performed at a pressure of 0.1 to 20 torr, as indicated at 1118. In other examples, pressures and/or radiofrequency powers outside of this range can be used.

At 1120, after performing the inert gas plasma pre-treatment, the method 1100 comprises exposing the substrate to a silicon-containing inhibitor to selectively adsorb the silicon-containing inhibitor to a metal surface and a barrier layer surface of the substrate. The silicon-containing inhibitor comprises one or more organic moieties. In some examples, the barrier layer surface comprises one or more of tantalum, ruthenium, or iridium, at 1122. As illustrative examples, the barrier layer surface can comprise tantalum nitride, at 1124.

As indicated at 1126, the silicon-containing inhibitor can comprise a head group comprising at least one Si—H group and a tail group comprising an organic moiety. For example, the silicon-containing inhibitor 130 of FIG. 1 comprises a head group 132 proximate to the metal surface 102 and a tail group 134 oriented away from the metal surface 102. In some such examples, this enables self-assembly of the silicon-containing inhibitor 130 into an inhibitor layer 1311. More specific examples of the silicon-containing inhibitor include n-octadecylsilane, tridecylsilane, dodecylsilane, undecylsilane, decylsilane, decan-4-ylsilane, nonylsilane, nonan-4-ylsilane, octan-2-ylsilane, octylsilane, heptylsilane, heptan-4-ylsilane, (tridecafluoro-1,1,2,2-tetra-hydrooctyl) silane, or 10-undecenylsilane.

With reference now to FIG. 11B, at 1130, the method 1100 further comprises exposing the substrate to a metal-containing precursor to adsorb the metal containing precursor to a dielectric surface of the substrate. The silicon-containing inhibitor inhibits adsorption of the metal-containing precursor to the metal surface and the barrier layer surface. In some examples, the dielectric surface can comprise one or more of SiO₂, doped SiO₂, Si₃N₄, SiC, SiOₓC_{y}, SiOₓN_{y}, or SiCₓN_{y}, as indicated at 1132. In some examples, the metal-containing precursor comprises an aluminum-containing precursor, as indicated at 1134. In other examples, the metal-containing precursor can comprise a different metal than aluminum. Example metal-containing precursors are described in more detail above. In some examples, the metal containing precursor can be used to form a catalytic layer on the dielectric surface of the substrate for the growth of a silicon oxide layer over the catalytic layer. In some such examples, the adsorbed metal-containing precursor can be used as the catalytic layer. In other such examples, an oxidizing agent can be introduced at 1136 into the processing chamber to oxidize the metal-containing precursor to form a metal oxide layer (e.g. aluminum oxide). The metal oxide layer can be used as a catalytic layer to help form an overlying silicon oxide layer, or can itself be used as a dielectric layer. In either case, at 1138, the exposing of the substrate to the metal-containing precursor and the oxidation of the metal-containing precursor can be repeated to form a thicker metal oxide film in a layer-by-layer manner using atomic layer deposition.

Examples of Al-containing precursors include one or more of MeAl(OPr)₂, MeAl(OⁱPr)₂, MeAl(OBu)₂, MeAl(O^{t}Bu)₂, MeAl(OEt)₂, Me₂Al(OPr), Me₂Al(OⁱPr), Me₂Al(OBu), Me₂Al(O^{t}Bu), Me₂Al(OEt), EtAl(OPr)₂, EtAl(OⁱPr)₂, EtAl(OBu)₂, EtAl(O^{t}Bu)₂, EtAl(OEt)₂, Et₂Al(OPr), Et₂Al(OⁱPr), Et₂Al(OBu), Et₂Al(O^{t}Bu), Et₂Al(OEt), PrAl(OPr)₂, PrAl(OⁱPr)₂, PrAl(OBu)₂, PrAl(O^{t}Bu)₂, PrAl(OEt)₂, Pr₂Al(OPr), Pr₂Al(OⁱPr), Pr₂Al(OBu), Pr₂Al(O^{t}Bu), or Pr₂Al(OEt).

In some examples, the oxidizing agent introduced at 1136 can comprise water. In other examples, the oxidizing agent can comprise an alcohol. In some such examples, the alcohol can comprise a 3-8 carbon alcohol. Some examples of suitable alcohols include isopropyl alcohol, 1-butyl alcohol, 2-butyl alcohol, or t-butyl alcohol.

In some more specific examples, the alcohol reacts with the Al-containing precursor without oxidizing the metal surface. As described above, in other examples, the adsorbed metal-containing precursor can serve as a catalytic layer without converting the adsorbed metal-containing precursor to Al₂O₃.

Where the metal oxide layer is used as a catalytic layer for growth of a silicon oxide layer, at 1140, the method 1100 comprises exposing the substrate to a silanol-based silicon oxide precursor, wherein the catalytic layer catalyzes a conversion of the silanol-based silicon oxide precursor to SiO₂. As described above, the catalytic layer converts the silanol-based silicon oxide precursor to a SiO₂ polymer that grows upward from the catalytic layer. Some examples of suitable silanol-based silicon oxide precursors include a silanol with one or more alkoxy groups, as indicated at 1142. Each alkoxy group can comprise one to seven carbon atoms.

As indicated at 1144, in some examples, introducing the silanol-based silicon oxide precursor comprises using flow-over-vapor to introduce the silanol-based silicon oxide precursor into the processing chamber. As described above, the silanol-based silicon oxide precursor can be in a condensed phase at standard pressure and temperature. Accordingly, a flow-over vapor delivery system (e.g., the flow-over vapor delivery system 419A of FIG. 4) can be used to volatilize the condensed phase silanol-based silicon oxide precursor and introduce the silanol-based silicon oxide precursor into the processing chamber. In other examples, other delivery systems can be used. Examples include vaporizer 419B, charged volume system 419C, and mole delivery system 419C. A mole delivery system 419C comprises a combination of a charged volume and a vaporizer system.

In some examples, at 1146, exposing the substrate to the silanol-based silicon oxide precursor comprises introducing the silanol-based silicon oxide precursor into the processing chamber in a plurality of pulses. As described above, cross-linking and thickening of the SiO₂ layer 152 can make it increasingly difficult for the additional molecules of the silanol-based silicon oxide precursor 150 to reach the catalytic layer 140 as the SiO₂ layer 152 grows. Providing the silanol-based silicon oxide precursor 150 in pulses 154 can help to balance diffusion, growth and cross-linking to enable controlled growth of the SiO₂ layer 152 on the catalytic layer 140.

At 1148, in some examples, the method 1100 optionally includes reapplying the catalytic layer at an intermediate time during the silicon oxide layer growth process. As described above, growth of the SiO₂ layer 152 of FIGS. 1A-1F slows the conversion of the silanol-based silicon oxide precursor 150 to the SiO₂ layer 152. Reapplication of the catalytic layer 140 on top of the SiO₂ layer 152 enables continued deposition of the SiO₂ layer 152 after an initial phase of growth of the silicon oxide slows or stops. After deposition of the dielectric layer (whether metal oxide or silicon oxide), after deposition is complete, method 1100 comprises removing the inhibitor from the metal surface and the barrier layer surface, at 1150.

Thus, the use of the silicon-containing inhibitor can allow for the deposition of metal oxide layers with reduced edge placement errors and tiger tooth errors compared to other deposition methods. The use of the inert gas plasma pre-treatment can allow for the silicon-containing inhibitor to adsorb to the barrier layer surface without the use of a pre-treatment comprising both an ammonia plasma process and a hydrogen/oxygen plasma process. Furthermore, silanol-based silicon oxide precursor-derived SiO₂ has a lower K than Al₂O₃. This can reduce RC delay relative to integrated circuit devices comprising higher-K materials. As a result, relatively smaller integrated circuit elements can be fabricated with similar accuracy to relatively larger integrated circuit elements using a same process.

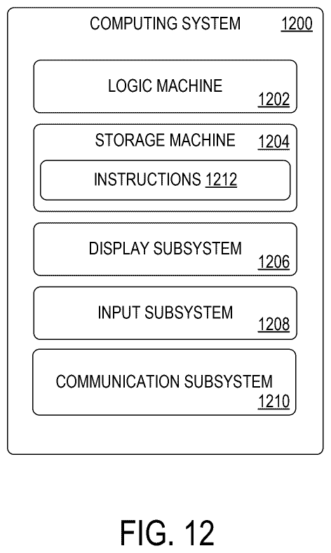

FIG. 12 schematically shows a non-limiting example of a computing system 1200 that can enact one or more of the methods and processes described above. Computing system 1200 is shown in simplified form. Computing system 1200 can take the form of one or more personal computers, workstations, computers integrated with substrate processing tools, and/or network accessible server computers.

Computing system 1200 includes a logic machine 1202 and a storage machine 1204. Computing system 1200 can optionally include a display subsystem 1206, input subsystem 1208, communication subsystem 1210, and/or other components not shown in FIG. 12. Controller 430, controller 529 and controller 1030 are examples of computing system 1200.

Logic machine 1202 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 1204 includes one or more physical devices configured to hold instructions 1212 executable by the logic machine to implement the methods and processes described herein. When such methods and processes are implemented, the state of storage machine 1204 can be transformed—e.g., to hold different data.

Storage machine 1204 can include removable and/or built-in devices. Storage machine 1204 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1204 can include volatile, nonvolatile, dynamic, static, read/write, read-only, random-access, sequential-access, location-addressable, file-addressable, and/or content-addressable devices.

It will be appreciated that storage machine 1204 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 1202 and storage machine 1204 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1206 can be used to present a visual representation of data held by storage machine 1204. This visual representation can take the form of a graphical user interface (GUI). As the herein described methods and processes change the data held by the storage machine, and thus transform the state of the storage machine, the state of display subsystem 1206 can likewise be transformed to visually represent changes in the underlying data. Display subsystem 1206 can include one or more display devices utilizing virtually any type of technology. Such display devices can be combined with logic machine 1202 and/or storage machine 1204 in a shared enclosure, or such display devices can be peripheral display devices.

When included, input subsystem 1208 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 1210 can be configured to communicatively couple computing system 1200 with one or more other computing devices. Communication subsystem 1210 can include wired and/or wireless communication devices compatible with one or more different communication protocols. As non-limiting examples, the communication subsystem can be configured for communication via a wireless telephone network, or a wired or wireless local- or wide-area network. In some examples, the communication subsystem can allow computing system 1200 to send and/or receive messages to and/or from other devices via a network such as the Internet.

This disclosure is presented by way of example and with reference to the associated drawing figures. Components, process steps, and other elements that can be substantially the same in one or more of the figures are identified coordinately and are described with minimal repetition. It will be noted, however, that elements identified coordinately can also differ to some degree. It will be further noted that some figures can be schematic and not drawn to scale. The various drawing scales, aspect ratios, and numbers of components shown in the figures can be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein comprises A, B, or a combination of A and B. The terminology “one or more of A, B, or C” is equivalent to A, B, and/or C. As such, “one or more of A, B, or C” as used herein comprises A individually, B individually, C individually, a combination of A and B, a combination of A and C, a combination of B and C, or a combination of A, B and C.

It will be understood that the configurations and/or approaches described herein are example in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for selectively depositing silicon oxide on a substrate, the substrate comprising a metal surface and a dielectric surface, the method comprising:
exposing the substrate to a silicon-containing inhibitor to selectively adsorb the silicon-containing inhibitor to the metal surface of the substrate, the silicon-containing inhibitor comprising one or more organic ligands;
forming a catalytic layer on the dielectric surface of the substrate by exposing the substrate to a metal-containing precursor to adsorb the metal-containing precursor to the dielectric surface, wherein the silicon-containing inhibitor inhibits adsorption of the metal-containing precursor to the metal surface; and
exposing the substrate to a silanol-based silicon oxide precursor, wherein the catalytic layer catalyzes a conversion of the silanol-based silicon oxide precursor to silicon oxide.

2. The method of claim 1, further comprising pre-treating the substrate with a plasma comprising oxygen and hydrogen before exposing the substrate to the silicon-containing inhibitor.

3. The method of claim 1, wherein the silicon-containing inhibitor comprises a head group comprising at least one Si—H group and a tail group comprising an organic moiety.

4. The method of claim 1, wherein the silicon-containing inhibitor comprises one or more of n-octadecylsilane, tridecylsilane, dodecylsilane, undecylsilane, decylsilane, decan-4-ylsilane, nonylsilane, nonan-4-ylsilane, octan-2-ylsilane, octylsilane, heptylsilane, heptan-4-ylsilane, (tridecafluoro-1,1,2,2-tetra-hydrooctyl) silane, or 10-undecenylsilane.

5. The method of claim 1, wherein the metal-containing precursor comprises an aluminum-containing precursor.

6. The method of claim 5, wherein forming the catalytic layer further comprises introducing an oxidizing agent into a processing chamber in which the substrate is located to thereby oxidize the aluminum-containing precursor and form an aluminum oxide layer on the dielectric surface.

7. The method of claim 1, wherein each alkoxy group of the silanol-based silicon oxide precursor comprises one to seven carbon atoms.

8. The method of claim 1, wherein the metal surface of the substrate comprises one or more of copper, cobalt, tungsten, ruthenium, rhodium, iridium tantalum, titanium, hafnium, zirconium, or molybdenum.

9. The method of claim 1, wherein the dielectric surface of the substrate comprises one or more of silicon dioxide, doped silicon dioxide, silicon nitride, silicon carbide, silicon oxycarbide, silicon oxynitride, or silicon carbon nitride.

10. The method of claim 1, wherein exposing the substrate to the silanol-based silicon oxide precursor comprises using flow-over-vapor to introduce the silanol-based silicon oxide precursor into a processing chamber in which the substrate is located.

11. The method of claim 1, further comprising reapplying the catalytic layer at an intermediate time after the substrate is exposed to the silanol-based silicon oxide precursor.

12. The method of claim 1, wherein exposing the substrate to the silanol-based silicon oxide precursor comprises introducing the silanol-based silicon oxide precursor in a plurality of pulses.

13. A method for processing a substrate, the method comprising:
exposing the substrate to a plasma comprising an inert gas to pre-treat the substrate;
exposing the substrate to a silicon-containing inhibitor to selectively adsorb the silicon-containing inhibitor to a metal surface and a barrier layer surface of the substrate, the silicon-containing inhibitor comprising one or more organic moieties; and
exposing the substrate to a metal-containing precursor to adsorb the metal-containing precursor to a dielectric surface of the substrate, wherein the silicon-containing inhibitor inhibits adsorption of the metal-containing precursor to the metal surface and the barrier layer surface.

14. The method of claim 13, wherein the inert gas comprises helium.

15. The method of claim 13, wherein the plasma further comprises one or more of hydrogen or ammonia.

16. The method of claim 13, wherein the silicon-containing inhibitor comprises one or more of n-octadecylsilane, tridecylsilane, dodecylsilane, undecylsilane, decylsilane, decan-4-ylsilane, nonylsilane, nonan-4-ylsilane, octan-2-ylsilane, octylsilane, heptylsilane, heptan-4-ylsilane, (tridecafluoro-1,1,2,2-tetra-hydrooctyl) silane, or 10-undecenylsilane.

17. The method of claim 13, wherein the metal-containing precursor comprises an aluminum-containing precursor.

18. The method of claim 17, wherein the barrier layer surface comprises one or more of tantalum, tantalum nitride, rhodium, or iridium.

19. A processing tool, comprising:
a processing chamber;
a substrate holder positioned within the processing chamber;
a plasma generator;
flow control hardware configured to control a flow of each of one or more processing chemicals into the processing chamber; and
a controller configured to
control the flow control hardware and the plasma generator to expose a substrate on the substrate holder to a plasma comprising an inert gas;
control the flow control hardware to expose the substrate on the substrate holder to a silicon-containing inhibitor to selectively adsorb the silicon-containing inhibitor to a metal surface and a barrier layer surface of the substrate, and
control the flow control hardware to expose the substrate to a metal-containing precursor to adsorb the metal-containing precursor to a dielectric surface of the substrate.

20. The processing tool of claim 19, further comprising an inert gas source, wherein the inert gas source comprises helium.
